(19) United States
(12) Patent Application Publication
(10) Pub. No.: US 2015/0160274 A1
(43) Pub. Date: Jun. 11, 2015

(54) METHOD AND APPARATUS FOR POWER ESTIMATION

(71) Applicants: FUJITSU LIMITED, Kawasaki-shi (JP); FUJITSU SEMICONDUCTOR LIMITED, Yokohama-shi (JP)

(72) Inventors: Toshiki OBARA, Kawasaki (JP); Hirohisa KOTEGAWA, Akiruno (JP); Naonobu HASUMI, Yokohama (JP)

(73) Assignees: FUJITSU LIMITED, Kawasaki-shi (JP); FUJITSU SEMICONDUCTOR LIMITED, Yokohama-shi (JP)

(21) Appl. No.: 14/557,665

(22) Filed: Dec. 2, 2014

(30) Foreign Application Priority Data
Dec. 6, 2013 (JP) 2013-252864

(51) Int. Cl. G01R 21/00; G01R 21/133

(52) U.S. Cl. CPC G01R 21/006; G01R 21/133

(57) ABSTRACT

A power estimation method includes acquiring power values consumed by a power estimation target apparatus, each of the power values corresponding to a plurality of parameters; calculating magnitude of variation in the power values in relation to a mean thereof; creating, when the magnitude of variation is less than a first value, a first power prediction formula approximating power consumption of the power estimation target apparatus by a constant which is the mean; calculating a degree of influence of each of the parameters on the power consumption when the magnitude of variation is the first value or more; creating, by reducing the number of the parameters based on the degree of influence, a second power prediction formula approximating the power consumption by a linear equation; and estimating the power consumption using one of the first and the second power prediction formulae.

### CROSS-REFERENCE TO RELATED APPLICATION

This application is based upon and claims the benefit of priority of the prior Japanese Patent Application No. 2013-252864, filed on Dec. 6, 2013, the entire contents of which are incorporated herein by reference.

### FIELD

The embodiments discussed herein are related to a method and an apparatus for power estimation.

### BACKGROUND

In the design of integrated circuits, information devices and the like, the power consumption of such a device is estimated in advance. One conventional method is to create a power model which abstracts the power consumption using parameters (for example, processor utilization and processor temperature) of a device whose power consumption is to be estimated, and estimate the power consumption using the power model. The power model is represented by a linear equation using the sum of products, each product formed by multiplying a parameter and a coefficient, and each coefficient is obtained, for example, by regression analysis.

Japanese Laid-open Patent Publication No. H10-11482

Japanese Laid-open Patent Publication No. H11-232147

Japanese Laid-open Patent Publication No. H5-265605

Japanese Laid-open Patent Publication No. H9-265487

However, the calculated amount of power estimation rises with an increased number of parameters of a power estimation target apparatus.

### SUMMARY

According to one embodiment, there is provided a power estimation method including acquiring, by a first processor, a plurality of power values consumed by a power estimation target apparatus, each of the power values corresponding to a plurality of parameters; calculating, by the first processor, magnitude of variation in the acquired power values in relation to a mean of the power values; creating, by the first processor, a first power prediction formula when the magnitude of variation is less than a first value, the first power prediction formula approximating power consumption of the power estimation target apparatus by a constant which is the mean; calculating, by the first processor, a degree of influence of each of the parameters on the power consumption when the magnitude of variation is more than or equal to the first value; creating, by the first processor, a second power prediction formula by reducing number of the parameters based on the degree of influence, the second power prediction formula approximating the power consumption by a linear equation; and estimating, by the first processor, the power consumption using one of the first power prediction formula and the second power prediction formula.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of a method and an apparatus for power estimation according to a first embodiment;

FIG. 2 illustrates an example of a power estimating apparatus according to a second embodiment;

FIG. 3 illustrates an exemplified flow of a power estimation method;

FIG. 4 is a first part of a flowchart illustrating an exemplified flow of power model creation processing;

FIG. 5 is a second part of the flowchart illustrating the exemplified flow of the power model creation processing;

FIG. 6 is a third part of the flowchart illustrating the exemplified flow of the power model creation processing;

FIG. 7 illustrates an example of power values included in input data;

FIG. 8 illustrates an example of parameter values included in the input data;

FIG. 9 illustrates an example of a screen for acquiring the input data;

FIG. 10 illustrates an example of an output screen of an evaluation result;

FIG. 11 illustrates a display example of regression analysis results;

FIG. 12 illustrates an example of an inquiry screen;

FIG. 13 illustrates an example of another inquiry screen;

FIG. 14 illustrates an exemplified flow of a power estimation method according to a third embodiment;

FIG. 15 illustrates an example of results of power model creation and evaluation;

FIG. 16 illustrates a simulation example of instruction type-specific correlations between MIPS ratings and power consumption;

FIG. 17 illustrates a simulation example of a correlation between MIPS ratings and power consumption for flip-flops;

FIG. 18 illustrates a simulation example of the correlation between MIPS ratings and power consumption for clock line-associated cells;

FIG. 19 illustrates a simulation example of the correlation between MIPS ratings and power consumption for memory;

FIG. 20 illustrates a simulation example of the correlation between MIPS ratings and power consumption for other power consuming factors (mainly combinational logic gates);

FIG. 21 illustrates a simulation example of the instruction type-specific correlations between the MIPS ratings and the power consumption for the flip-flops;

FIG. 22 illustrates a simulation example of the instruction type-specific correlations between the MIPS ratings and the power consumption for the clock line-associated cells;

FIG. 23 illustrates a simulation example of the instruction type-specific correlations between the MIPS ratings and the power consumption for the memory;

FIG. 24 illustrates a simulation example of the instruction type-specific correlations between the MIPS ratings and the power consumption for the other power consuming factors;

FIG. 25 illustrates an example of an input data acquisition method;

FIG. 26 illustrates an example of calculated power values and MIPS ratings;

FIG. 27 illustrates an example of a start screen of power library creation processing;

FIG. 28 is a flowchart illustrating an exemplified flow of the power library creation processing;

FIG. 29 illustrates an example of a power library;

FIG. 30 illustrates an example of a start screen of power estimation processing;

FIG. 31 illustrates an example of a table for designating a parameter value;

FIG. 32 is a flowchart illustrating a modification of the power library creation processing;

FIG. 33 illustrates a simulation example of the correlation between the MIPS ratings and the power consumption;

FIG. 34 illustrates a simulation example of the correlation between the MIPS ratings multiplied by activity factors and the power consumption;

FIG. 35 illustrates a simulation example of instruction type-specific correlations between the MIPS ratings multiplied by the activity factors and the power consumption;

FIG. 36 illustrates another example of the input data acquisition method;

FIG. 37 illustrates an example of calculated power values, MIPS ratings, and activity factors;

FIG. 38 illustrates another example of the start screen of the power library creation processing;

FIG. 39 is a flowchart illustrating another exemplified flow of the power library creation processing;

FIG. 40 illustrates another example of the start screen of the power estimation processing;

FIG. 41 illustrates an example of a table for a function ρ(est_m, p_type);

FIG. 42 illustrates an example of the acquired input data; and

FIG. 43 is a flowchart illustrating yet another exemplified flow of the power library creation processing.

### DESCRIPTION OF EMBODIMENTS

Several embodiments will be described below with reference to the accompanying drawings, wherein like reference numerals refer to like elements throughout.

### (a) First Embodiment

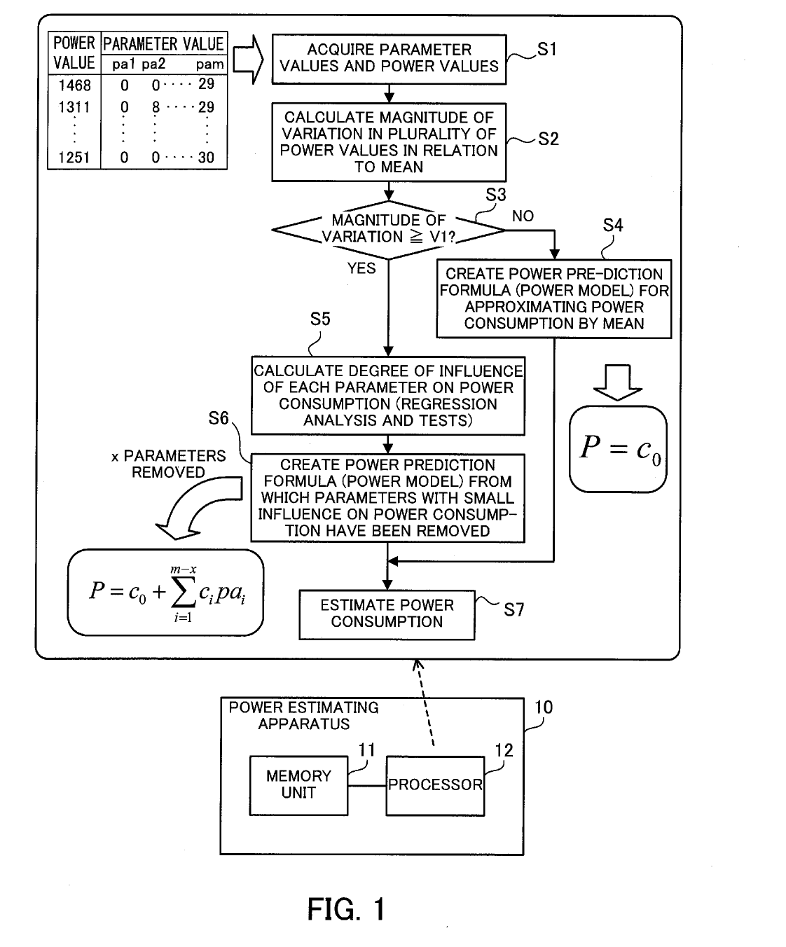

FIG. 1 illustrates an example of a method and an apparatus for power estimation according to a first embodiment. A power estimating apparatus 10 includes a memory unit 11 and a processor 12. The processor 12 executes the following power estimation method based on data and programs stored in the memory unit 11.

First, according to values of a plurality of parameters, the processor 12 acquires a plurality of power values consumed by a power estimation target apparatus (a processor, a large-scale integrated circuit (LSIC), an electrical device, or the like), which power values are stored in the memory unit 11 (step S1). Parameters pa1, pa2, . . . and pam are, for example, processor utilization, disk access speed, network use band, used amount of physical memory, and processor temperature. In step S1, a plurality of power values are acquired, each of which corresponds to a combination of these parameters pa1 to pam. The power values according to values of the parameters pa1 to pam are preliminarily calculated, for example, by simulations using design information and the like and then stored in the memory unit 11. Alternatively, such power values may be obtained from actual measurements on an apparatus having the same parameters as the power estimation target apparatus and then stored in the memory unit 11.

After step S1, the processor 12 calculates the magnitude of variation in the acquired power values in relation to the mean of the power values (step S2). The magnitude of variation is expressed by the coefficient of variation (CV), which is defined as the ratio of the standard deviation of the acquired power values to their mean. The processor 12 determines whether the magnitude of variation calculated in step S2 is more than or equal to a predetermined value V1 (step S3). Then, if the magnitude of variation is less than the value V1, the processor 12 creates a power prediction formula (power model) for approximating the power consumption of the target apparatus by a constant, which is the mean of the power values (step S4). According to the example of FIG. 1, P=c₀ is the power model where c₀ is the mean of the power values. Herewith, when the amount of variation in the power values around the mean is small, the power model is able to be expressed by the constant. Thus, the power model is simplified, reducing the calculated amount of the power estimation.

If the magnitude of variation is more than or equal to the value V1, the processor 12 calculates the degree of influence of each of the parameters pa1 to pam on the power consumption (estimated power) (step S5). Some of the parameters pa1 to pam may have small influence on the power consumption and are, therefore, unwanted in the power model. In step S5, such parameters are detected, for example, by regression analysis and tests. As an index representing the degree of influence on the power consumption, the significance probability (also called “p-value”) of a coefficient (partial regression coefficient) in a t-test, for example, is used. An example of the test using the p-value is described later.

Based on the degree of influence of each of the parameters pa1 to pam on the power consumption, calculated in step S5, the processor 12 removes at least one of the parameters pa1 to pam, having the least influence on the power consumption, and then creates a power model (step S6). For example, when x parameters are removed sequentially in ascending order of influence on the estimated power, the power model is represented by the following equation (1).

$$P = {c}_{0} + {\sum }_{i = 1}^{m - x} {c}_{i} {pa}_{i} \qquad ( 1 )$$

P is the estimated power, c₀ is the mean of the power values, m is the number of input parameters, and cᵢ is the coefficient of the i^{th} parameter paᵢ among remaining parameters (i.e., parameters left unremoved). The coefficient cᵢ is determined by the regression analysis in step S5.

Subsequently, the processor 12 estimates the power consumption of the power estimation target apparatus using the power model obtained in step S4 or the power model obtained in step S6 (step S7). For example, when the power model obtained in step S4 is employed, the power consumption P is the mean (c₀) of the power values. When the power model obtained in step S6 is employed, the power consumption P is obtained by equation (1) into which, for example, parameter values input by a user (which values may be different from the values of the parameters pa1 to pam acquired in step S1) are substituted.

As described above, according to the power estimation method and the power estimating apparatus 10 of the first embodiment, the number of parameters used in the power model is reduced in consideration of the influence of each parameter on the power consumption. Thus, the calculated amount of the power estimation is reduced without sacrificing estimation accuracy.

### (b) Second Embodiment

Next described is an example of an apparatus and a method for power estimation according to a second embodiment.

(Example of Power Estimating Apparatus)

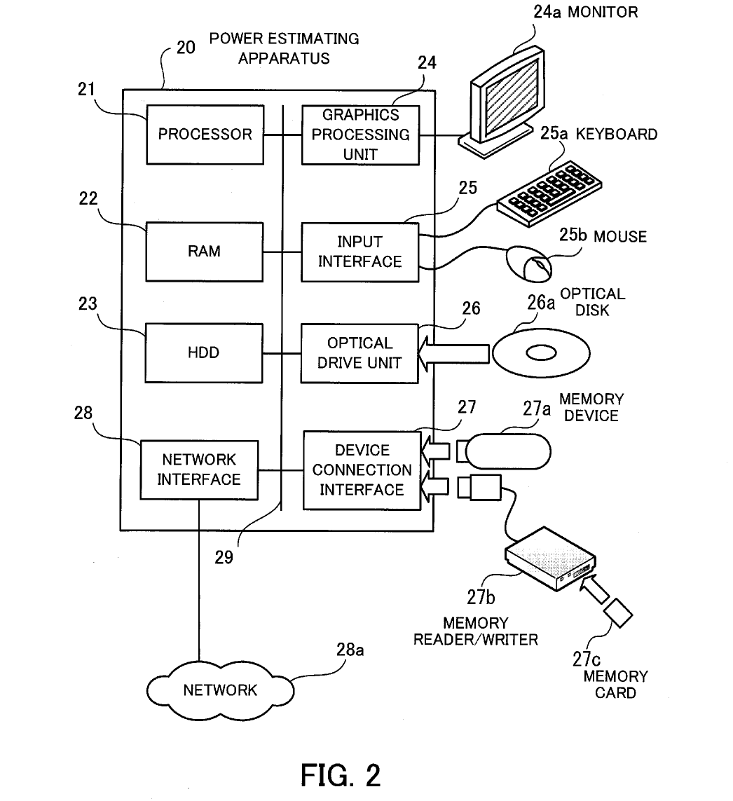

FIG. 2 illustrates an example of a power estimating apparatus according to the second embodiment. A power estimating apparatus 20 is, for example, a computer, and overall control of the power estimating apparatus 20 is exercised by a processor 21. To the processor 21, random access memory (RAM) 22 and a plurality of peripherals are connected via a bus 29. The processor 21 may be a multi-processor. The processor 21 is, for example, a central processing unit (CPU), a micro processing unit (MPU), a digital signal processor (DSP), an application specific integrated circuit (ASIC), a programmable logic device (PLD), or a combination of two or more of these.

The RAM 22 is used as a main storage device of the power estimating apparatus 20. The RAM 22 temporarily stores at least part of an operating system (OS) program and application programs to be executed by the processor 21. The RAM 22 also stores therein various types of data to be used by the processor 21 for its processing.

The peripherals connected to the bus 29 include a hard disk drive (HDD) 23, a graphics processing unit 24, an input interface 25, an optical drive unit 26, a device connection interface 27, and a network interface 28. The HDD 23 magnetically writes and reads data to and from a built-in disk, and is used as a secondary storage device of the power estimating apparatus 20. The HDD 23 stores therein the OS program, application programs, and various types of data. Note that a semiconductor storage device such as a flash memory may be used as a secondary storage device in place of the HDD 23. To the graphics processing unit 24, a monitor 24a is connected. According to an instruction from the processor 21, the graphics processing unit 24 displays an image on a screen of the monitor 24a. A cathode ray tube (CRT) display or a liquid crystal display, for example, may be used as the monitor 24a.

To the input interface 25, a keyboard 25a and a mouse 25b are connected. The input interface 25 transmits signals sent from the keyboard 25a and the mouse 25b to the processor 21. Note that the mouse 25b is just an example of pointing devices, and a different pointing device such as a touch panel, a tablet, a touch-pad, and a track ball, may be used instead. The optical drive unit 26 reads data recorded on an optical disk 26a using, for example, laser light. The optical disk 26a is a portable storage medium on which data is recorded to be read by reflection of light. Examples of the optical disk 26a include a digital versatile disc (DVD), a DVD-RAM, a compact disc read only memory (CD-ROM), a CD recordable (CD-R), and a CD-rewritable (CD-RW).

The device connection interface 27 is a communication interface for connecting peripherals to the power estimating apparatus 20. To the device connection interface 27, for example, a memory device 27a and a memory reader/writer 27b may be connected. The memory device 27a is a storage medium having a function for communicating with the device connection interface 27. The memory reader/writer 27b is a device for writing and reading data to and from a memory card 27c. The memory card 27c is a card type storage medium. The network interface 28 is connected to a network 28a. Via the network 28a, the network interface 28 transmits and receives data to and from different computers and communication devices.

The hardware configuration described above achieves the processing functions of the second embodiment. Note that the power estimation apparatus 10 of the first embodiment may be built with the same hardware configuration as the power estimating apparatus 20 of FIG. 2.

The power estimating apparatus (computer) 20 achieves the processing functions of the second embodiment, for example, by implementing a program stored in a computer-readable storage medium. The program describing processing contents to be implemented by the power estimating apparatus 20 may be stored in various types of storage media. For example, the program to be implemented by the power estimating apparatus 20 may be stored in the HDD 23. The processor 21 loads at least part of the program stored in the HDD 23 into the RAM 22 and then runs the program. In addition, the program to be implemented by the power estimating apparatus 20 may be stored in a portable storage medium, such as the optical disk 26a, the memory device 27a, and the memory card 27c. The program stored in the portable storage medium becomes executable after being installed on the HDD 23, for example, under the control of the processor 21. Alternatively, the processor 21 may run the program by directly reading it from the portable storage medium.

(Example of Power Estimation Method)

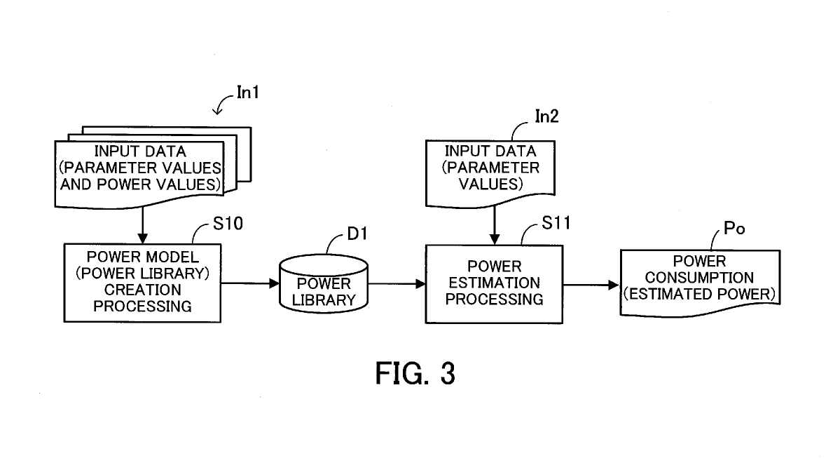

FIG. 3 illustrates an exemplified flow of a power estimation method.

The power estimating apparatus 20 carries out power model (power library) creation processing (step S10) and power estimation processing (step S11), as illustrated in FIG. 3.

In the power model (power library) creation processing, the processor 21 creates a power model by acquiring input data In1 including parameter values and power values, for example, stored in the HDD 23. Note that, in the power model creation processing, the power model is output as a power library D1 including a list of coefficients of the power model expressed by equation (1), which power library D1 is then stored in the HDD 23, for example.

In the power estimation processing, the processor 21 acquires, from a user, parameter values as input data In2, and applies the parameter values to the power model represented by the power library D1 to thereby calculate power consumption (estimated power) Po. Then, the processor 21 causes, for example, the graphics processing unit 24 to display the calculated power consumption Po onto the monitor 24a.

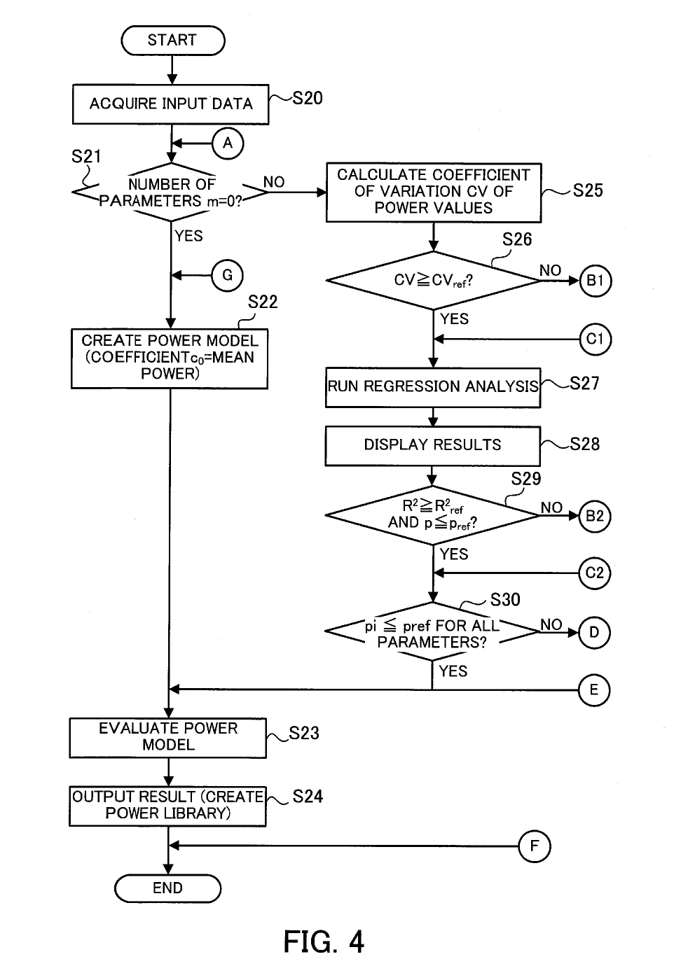

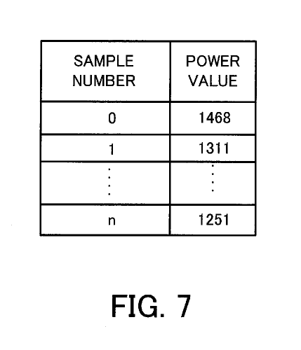

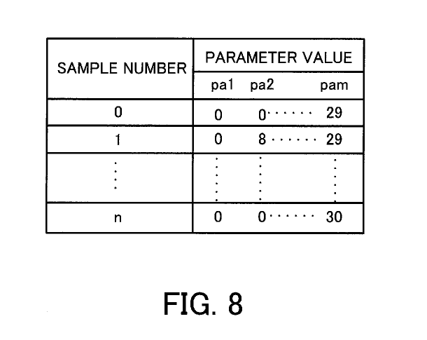

Next described is an example of the power model creation processing. FIGS. 4, 5, and 6 are flowcharts illustrating an exemplified flow of power model creation processing. Note that the sequence of individual processing steps is just an example, and the order of the processing steps may be changed accordingly. First, the processor 21 acquires input data (step S20). FIG. 7 illustrates an example of power values included in input data. The exemplified power values of FIG. 7 are those obtained from samples of the power estimation target apparatus, each identified with a sample number. FIG. 8 illustrates an example of parameter values included in the input data. The exemplified parameter values pa1 to pam of FIG. 8 are those of the samples of the power estimation target apparatus, each identified with a sample number. The parameters pa1 to pam are, for example, processor utilization, disk access speed, network use band, used amount of physical memory, and processor temperature.

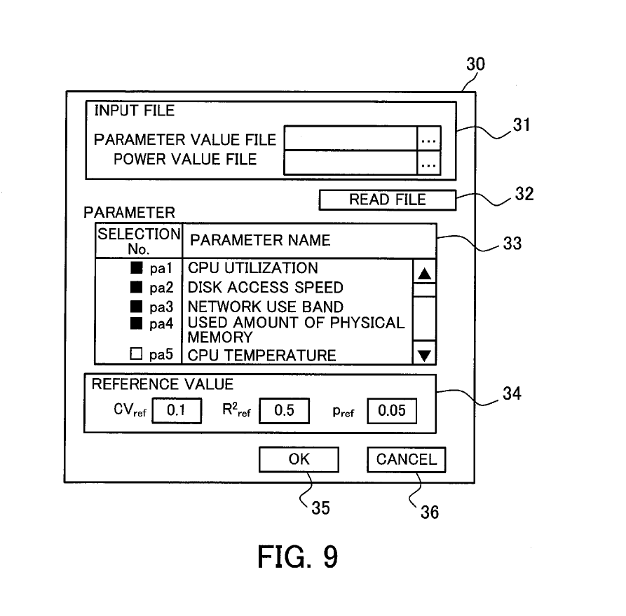

FIG. 9 illustrates an example of a screen for acquiring the input data. In an input file designation section 31 on a screen 30, a power value file with power values, like those of FIG. 7, stored therein and a parameter value file with parameter values, like those of FIG. 8, stored therein are selected by the user operating the mouse 25b or the like. Then, when a read file button is pressed, the selected files are read and, then, parameter names of the parameters pa1 to pam are displayed on a parameter selection window 33, which allows the user to select parameters to be used. Further, in a reference value input section 34, reference values CV_{ref}, R²_{ref}, and p_{ref} used in determination processing to be described later are input, for example, by the user. In the reference value input section 34, predetermined values, for example, CV_{ref}=0.1, R²_{ref}=0.5, and p_{ref}=0.05 may have been input in advance as default values. In response to a press on an OK button 35, data selected and/or input by the user is acquired as the input data In1. If a cancel button 36 is pressed, the acquisition of the input data In1 is cancelled.

After acquiring the input data in the above described manner, the processor 21 proceeds to step S21 of FIG. 4. In step S21, the processor 21 determines whether the number of parameters, m, is 0. If the number of parameters m is 0, the processor 21 proceeds to step S22. If not, the processor 21 proceeds to step S25.

In step S22, the processor 21 calculates the mean of the acquired power values (mean power) and creates a power model where the coefficient c₀ equals the mean power (step S22). The power model created in step S22 represents the power consumption by the constant. In step S22, the processor 21 may cause the monitor 24a to display the calculated power model.

After step S22, the processor 21 proceeds to step S23. In step S23, the processor 21 evaluates the created power model. The evaluation of the power model is made using a relative error REⱼ calculated, for example, by the following equation (2).

$${RE}_{j} = \frac{( {c}_{0} + {\sum }_{i = 1}^{m} {c}_{i} {pa}_{i , j} - {y}_{j} )}{{y}_{j}} \qquad ( 2 )$$

In equation (2), i is the parameter number, j is the sample number, and yⱼ is the power value of a sample with the sample number j. Note that the relative error REⱼ equals to (c₀−yⱼ)/yⱼ when the number of parameters m is 0.

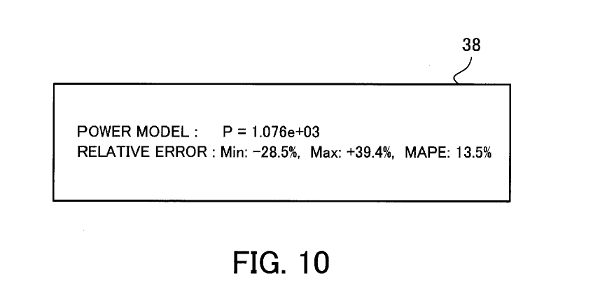

After step S23, the evaluation result is output, and the power library D1 including calculated coefficients and constant is created (step S24). FIG. 10 illustrates an example of an output screen of an evaluation result. An example of the power model obtained when the number of parameters m is 0 is presented on an output screen 38. The relative error is represented by three values: its minimum and maximum values Min and Max, and mean absolute percentage error (MAPE, the average of absolute values of relative errors of individual samples).

In step S25, to which the processor 21 proceeds when the number of parameters m is determined not to be 0 in step S21 of FIG. 4, the processor 21 calculates the coefficient of variation CV representing the magnitude of variation in the power values relative to the mean. The coefficient of variation CV is expressed as the ratio of the standard deviation of the power values to the mean of the power values, that is, CV=standard deviation/mean.

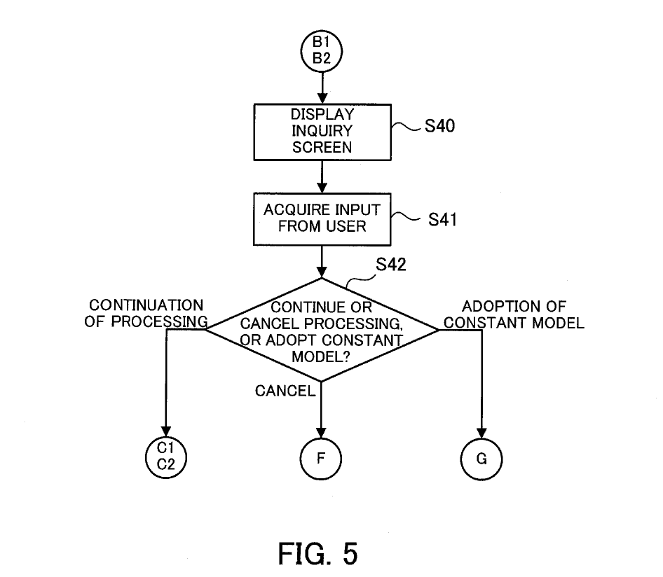

After calculating the coefficient of variation CV, the processor 21 compares the coefficient of variation CV against the reference value CV_{ref} acquired in step S20 to determine if CV≧CV_{ref} (step S26). If determining that CV≧CV_{ref}, the processor 21 proceeds to step S27. If not, the processor 21 proceeds to step S40 of FIG. 5. The reference value CV_{ref} is set accordingly, for example, to 0.1 or 0.01 by the user on the screen 30 illustrated in FIG. 9. As described later, when CV≧CV_{ref} is not satisfied, the power model is approximated by the mean power. Therefore, if a large error is obtained in the evaluation of the power model, the processor 21 may acquire a smaller value for the reference value CV_{ref} to thereby make the power model less likely to be approximated by the mean power.

In step S27, the processor 21 runs regression analysis. In the regression analysis, the linear equation of the power model expressed by equation (1) is used as an regression equation (note however that i in equation (1) is 1 to m since no parameters are removed at this point). The processor 21 substitutes the power values and parameter values acquired in step S20 in equation (1) to thereby obtain the coefficient cᵢ using the least squares method or the like. In step S27, the processor 21 further calculates the coefficient of determination R² defined as R₂=(Q−Qₑ)/Q, where Q is the variation in the power values and Qₑ is the residual sum of squares. The variation is the sum of the squared differences between the power value of each sample and the mean power. The residual sum of squares is the sum of the squared differences between the power value of each sample and a power value of the sample calculated by the obtained power model.

The coefficient of determination R² represents the accuracy of the regression equation obtained from the regression analysis. A small coefficient of determination R² means that the regression equation to be a power model used to estimate power has poor accuracy in the estimation, and a large coefficient of determination R² means that the regression equation has high estimation accuracy. Note that the coefficient of determination R² tends to increase as the number of parameters increases, and therefore the processor 21 may calculate the coefficient of determination adjusted for the degrees of freedom (hereinafter simply referred to as the “adjusted coefficient of determination”) which adjusts for an increase in the number of parameters.

In addition, the processor 21 calculates the significance probability of a test of the coefficient of determination R² and the significance probability of a test of a coefficient (partial regression coefficient). The test of the coefficient of determination R² is based on the theory that the variance ratio F (=(variance of the regression)/(variance of the residuals)) follows an F distribution (F (m, n−m−1)) with the numerator degree of freedom m (the number of parameters) and the denominator degree of freedom n−m−1 (n is the number of samples). The test of the coefficient of determination R² calculates the probability, based on the assumption that the coefficient of determination R² is 0 (i.e., there is zero correlation between parameter values and power values obtained for the parameter values), that a power value calculated by the regression equation matches an input power value due to sampling error. The probability is the significance probability (p-value) of the test of the coefficient of determination R².

The test of the partial regression coefficient is based on the theory that the t-statistic (=coefficient/(standard error)) follows a t-distribution (t (n−p−1)) with n−p−1 degrees of freedom. The test of the partial regression coefficient calculates the probability, based on the assumption that the coefficient of a parameter value is 0, that a power value calculated by the regression equation matches an input power value due to sampling error. The probability is the significance probability (p-value) of the test of the partial regression coefficient.

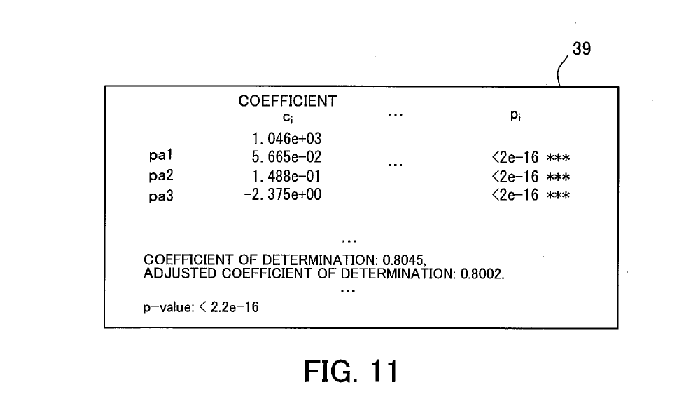

The processor 21 causes, for example, the monitor 24a to display results of the above-described regression analysis (step S28). FIG. 11 illustrates a display example of regression analysis results.

A screen 39 displays a calculated result of the coefficient cᵢ for each of the parameters pa1 to pa3. Note that the first value in the column of the coefficient cᵢ is the calculated value of c₀ (constant term). The column of pᵢ includes the significance probability of each of the parameters pa1 to pa3. According to the example of FIG. 11, each significance probability pᵢ is less than 2e-16 (i.e., 2×10⁻¹⁶). In addition, FIG. 11 also provides results of the coefficient of determination R², the adjusted coefficient of determination, and the significance probability of the coefficient of determination. According to the example of FIG. 11, the significance probability of the coefficient of determination is less than 2.2e-16.

Referring back to the flowchart of FIG. 4, after step S28, the processor 21 determines whether the coefficient of determination R² is more than or equal to the reference value R²_{ref} and the significance probability p of the coefficient of determination R² is less than or equal to a reference value p_{ref}, i.e., R²≧R²_{ref} and p≦p_{ref} (step S29). The reference value R²_{ref} is, for example, 0.5. When R²<0.5, errors obtained tend not to be much different whether the power model is represented by a linear equation, like equation (1), or by the constant (mean power). In addition, when the significance probability p of the coefficient of determination R² is sufficiently large, there is not much difference in the errors even with the model being represented by the mean power. The reference value p_{ref} is, for example, 0.05. When R²≧R²_{ref} and p≦p_{ref}, the processor 21 proceeds to step S30, and when R²<R²_{ref} or p>p_{ref}, the processor 21 proceeds to step S40 of FIG. 5.

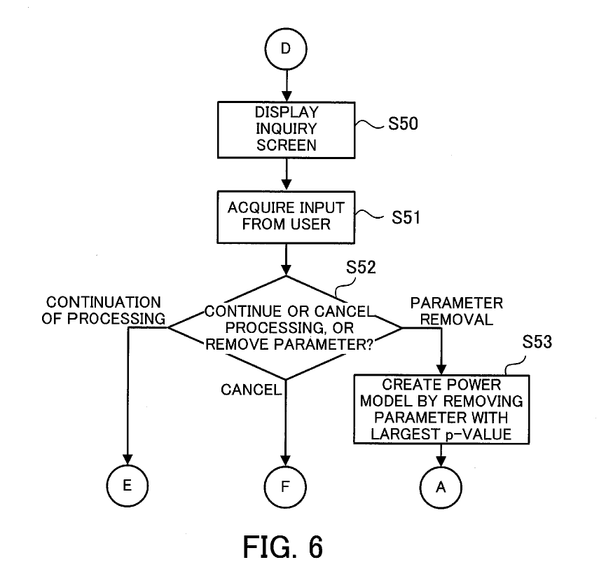

In step S30, the processor 21 determines whether the significance probability pᵢ of each of all the parameters paᵢ is less than or equal to the reference value p_{ref}. If the significance probability pᵢ of all the parameters paᵢ is less than or equal to the reference value p_{ref}, the processor 21 proceeds to step S23 described above. If the significance probability pᵢ of one or more of the parameters paᵢ is more than the reference value p_{ref}, these parameters are determined not to be useful for the power estimation and the processor 21 proceeds to step S50 of FIG. 6.

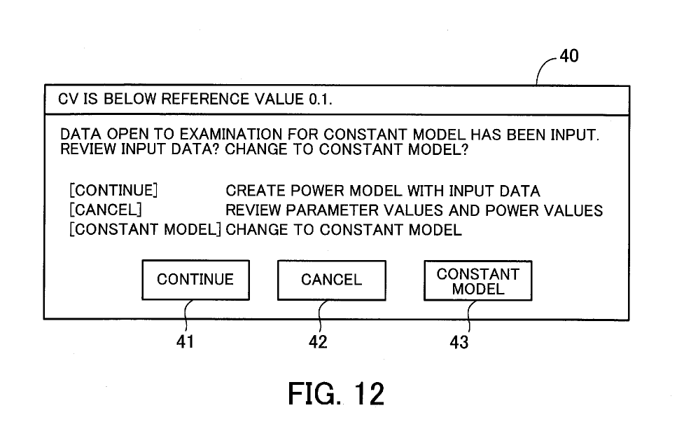

The processor 21 proceeds to step S40 of FIG. 5 when having determined, in step S26, that CV≧CV_{ref} is not satisfied or when having determined, in step S29, that R²≧R²_{ref} and p≦p_{ref} are not satisfied. In step S40, the processor 21 causes the monitor 24a to display, for example, the following inquiry screen. FIG. 12 illustrates an example of an inquiry screen. The example illustrated in FIG. 12 is an inquiry screen 40 displayed when the coefficient of variation CV falls below the reference value CV_{ref} (0.1 in the example of FIG. 12). The inquiry screen 40 prompts the user to select one of the following options: to express the power model by the constant (constant model); to create the power model using the input data; and to review the input parameter values and power values. The inquiry screen 40 of FIG. 12 includes buttons 41, 42, and 43, and one of the buttons 41 to 43 is pressed by the user operating the mouse 25b, or the like, according to a selection out of the three options above. Herewith, the processor 21 acquires an input from the user (step S41).

Then, the processor 21 determines whether the input of the user indicates the continuation or the cancellation of the processing, or the adoption of the constant model (step S42). For example, when the button 41 is pressed on the inquiry screen 40 of FIG. 12, the processor 21 determines that the continuation of the processing (i.e., the creation of a power model using the input data) has been instructed. After determining that the continuation of the processing has been instructed, the processor 21 proceeds to step S27 or S30 described above. Specifically, when having proceeded to step S40 from step S26, the processor 21 carries out step S27. When having proceeded to step S40 from step S29, the processor 21 carries out step S30.

When the button 42 is pressed on the inquiry screen 40, the processor 21 determines that the cancellation of the processing has been instructed, and ends the power model (power library) creation processing. When the button 43 is pressed on the inquiry screen 40, the processor 21 determines that the adoption of a constant model has been instructed. After determining that the adoption of a constant model has been instructed, the processor 21 proceeds to step S22 described above.

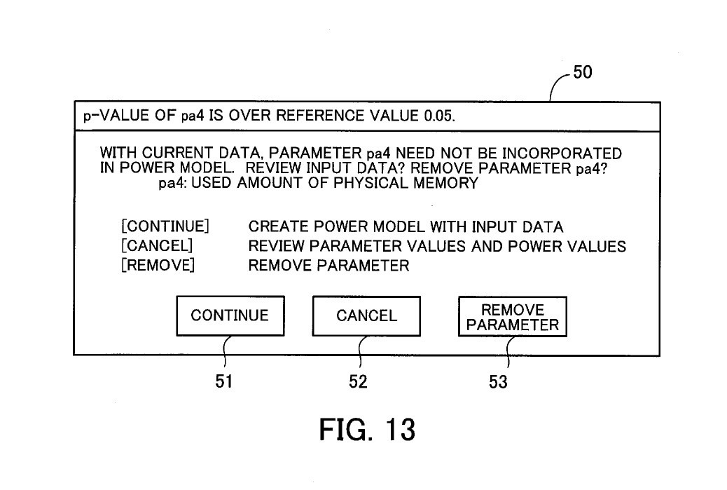

On the other hand, when, in step S30 described above, there is determined to be one or more parameters with pᵢ>p_{ref}, the processor 21 proceeds to step S50 of FIG. 6. In step S50, the processor 21 causes the monitor 24a to display, for example, the following inquiry screen. FIG. 13 illustrates an example of another inquiry screen. The example illustrated in FIG. 13 is an inquiry screen 50 displayed when the p-value (significance probability) of the parameter pa4 is more than the reference value p_{ref} (0.05 in the example of FIG. 13). The inquiry screen 50 prompts the user to select one of the following options: to remove the parameter pa4 from the power model creation; to create a power model with the input data; and to review the input parameter values and power values. Note that if there are a plurality of parameters with the p-value exceeding the reference value p_{ref}, the inquiry screen 50 of FIG. 13 is displayed, for example, for a parameter with the largest p-value among these parameters.

The inquiry screen 50 of FIG. 13 includes buttons 51, 52, and 53, and one of the buttons 51 to 53 is pressed by the user operating the mouse 25b, or the like, according to a selection out of the three options above. Herewith, the processor 21 acquires an input from the user (step S51). Then, the processor 21 determines whether the input of the user indicates the continuation or the cancellation of the processing, or the removal of the parameter (step S52). For example, when the button 51 is pressed on the inquiry screen 50 of FIG. 13, the processor 21 determines that the continuation of the processing (i.e., the creation of a power model using the input data) has been instructed. After determining that the continuation of the processing has been instructed, the processor 21 proceeds to step S23 described above.

When the button 52 is pressed on the inquiry screen 50, the processor 21 determines that the cancellation of the processing has been instructed, and ends the power model (power library) creation processing. When the button 53 is pressed on the inquiry screen 50, the processor 21 determines that parameter removal has been instructed, and creates a power model after removing, for example, the parameter with the largest p-value (step S53). Subsequently, the processor 21 proceeds to step S21 described above.

The processor 21 uses the power model created through the above-described processing to carry out the power estimation processing. According to the power estimating apparatus 20 and the power estimation method of the second embodiment, the number of parameters incorporated in the power model is reduced in consideration of the influence of each parameter on the power consumption to be predicted. Thus, the calculated amount of the power estimation is reduced without sacrificing estimation accuracy.

Note that, as described above, the coefficient of variation CV used in the second embodiment is easily calculated only using the input data (parameter values and power values), and the significance probability is calculated by regression analysis. Therefore, the second embodiment involves less amount of calculation compared, for example, to the case of calculating a relative error to assess the validity of the input data in the power model creation. In addition, by displaying the inquiry screens 40 and 50 of FIGS. 12 and 13, respectively, prior to approximation of a power model by the mean power and removal of a parameter, the user is able to check in advance parameter values and power values to be input.

### Third Embodiment

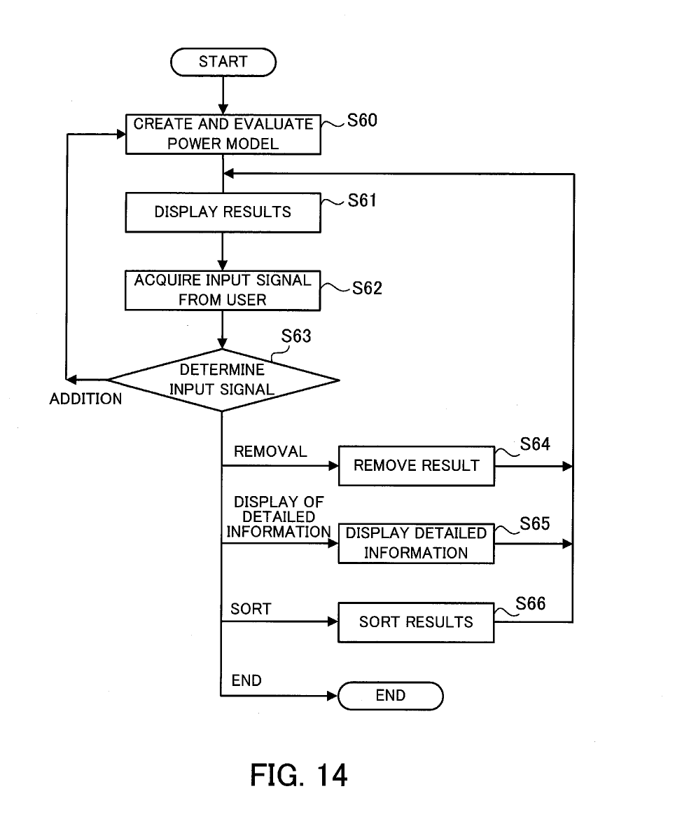

Next described is a power estimation method according to a third embodiment. As for a power estimating apparatus, the power estimating apparatus 20 of FIG. 2 is applicable. FIG. 14 illustrates an exemplified flow of a power estimation method according to the third embodiment. Note that the sequence of individual processing steps is just an example, and the order of the processing steps may be changed accordingly.

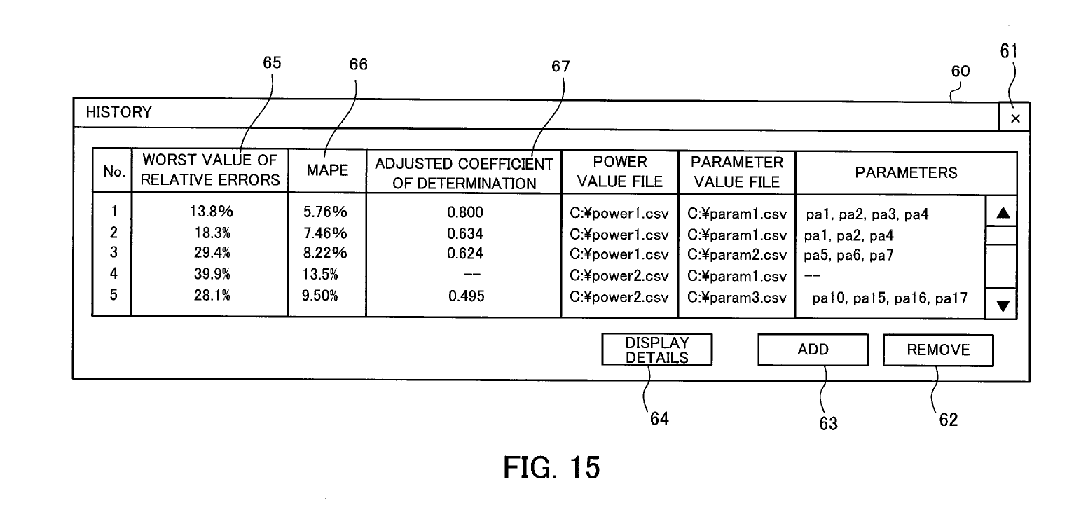

In step S60, the processor 21 creates a power model and evaluates the power model as illustrated in FIGS. 4 to 6. Subsequently, the processor 21 causes the monitor 24a to display, for example, the following information to thereby present the user with results of step S60 (step S61). FIG. 15 illustrates an example of results of power model creation and evaluation. A screen displays a history of results of the power model creation and evaluation of samples with sample numbers No. 1 to No. 5.

With respect to each sample, the following information is given: the worst value of relative errors (the maximum value of the absolute values); MAPE (mean absolute percentage error, the average of the absolute values of the relative errors); the adjusted coefficient of determination; a power value file used; a parameter value file used; and parameters used.

In addition, the screen 60 includes buttons 61, 62, 63, and 64. For example, one of the buttons 61 to 64 is pressed by the user operating the mouse 25b or the like. To sort the information (for example, to sort the results according to records in the column of “worst value of relative errors”, “MAPE”, or “adjusted coefficient of determination” in descending or ascending order), a column with a corresponding title 65, 66, or 67 is pressed by the user operating the mouse 25b or the like.

Then, the processor 21 acquires an input signal from the user operating the mouse 25b or the like (step S62). Subsequently, the processor 21 determines the input signal acquired from the user (step S63). For example, when the button 61 is pressed on the screen 60 of FIG. 15, the processor 21 determines that the user has instructed to end the power model creation, evaluation, and display processing. In this case, the processor 21 ends the power model creation, evaluation, and display processing. When the button 62 is pressed on the screen 60, the processor 21 determines that removal of a result designated by the user operating the mouse 25b, or the like, from the screen 60 has been instructed by the user. In this case, under the control of the processor 21, the designated result is removed from the screen 60 (step S64). Then, the processor 21 proceeds to step S61.

When the button 63 is pressed on the screen 60, the processor 21 determines that the user has instructed to create and evaluate a power model for a new sample and then add the result. In this case, after step S60 is carried out for the new sample, the result is added to the screen 60. When the button 64 is pressed on the screen 60, the processor 21 determines that the user has instructed to display detailed information. In this case, detailed information on a result selected before the button 64 is pressed is displayed on the screen 60 (step S65). Subsequently, the processor 21 returns to step S61 and repeats operations subsequent to step S61. The detailed information is, for example, a corresponding power model (power prediction formula) and an evaluation index based on a relative error obtained when the power model is applied.

When one of the columns 65, 66, and 67 with the result titles is pressed, the processor 21 determines that the user has instructed to sort the information. In this case, the results on the screen 60 are sorted according to records in the selected column in descending or ascending order (step S66). Subsequently, the processor 21 returns to step S61 and repeats operations subsequent to step S61.

According to the power estimation method of the third embodiment described above, the user is presented with changes in evaluation results of estimated power consumption, caused by a change in parameters used to create a power model. Herewith, the power estimation method of the third embodiment achieves the same effect as the second embodiment, and further facilitates the user in comparing evaluation results of a corresponding power model of each sample with a change in the parameters, thus alleviating the burden on the user.

### (d) Fourth Embodiment

Next described is a power estimation method according to a fourth embodiment. As for a power estimating apparatus, the power estimating apparatus 20 of FIG. 2 is applicable. According to the power estimation method of the fourth embodiment, its power estimation target apparatus is a semiconductor integrated circuit (for example, a system on a chip (SoC)) including a processor, such as a CPU and a DSP. In the power estimation method of the fourth embodiment, a power model taking account of power consuming factors in the processor and instruction types of the processor is created.

As for semiconductor integrated circuits including a processor, power is predominantly consumed by the processor and it is, therefore, desirable to predict the power with a small margin of error. Instructions of the processor includes those predominantly involving integer arithmetic (hereinafter referred to as the “integer-type instructions”) and those predominantly involving floating-point arithmetic (the “floating-point-type instructions”), and circuits executing the individual types of instructions are considered to consume different amounts of power. Therefore, a linear expression simply using a million instructions per second (MIPS) rating does not produce an accurate prediction of the power consumption.

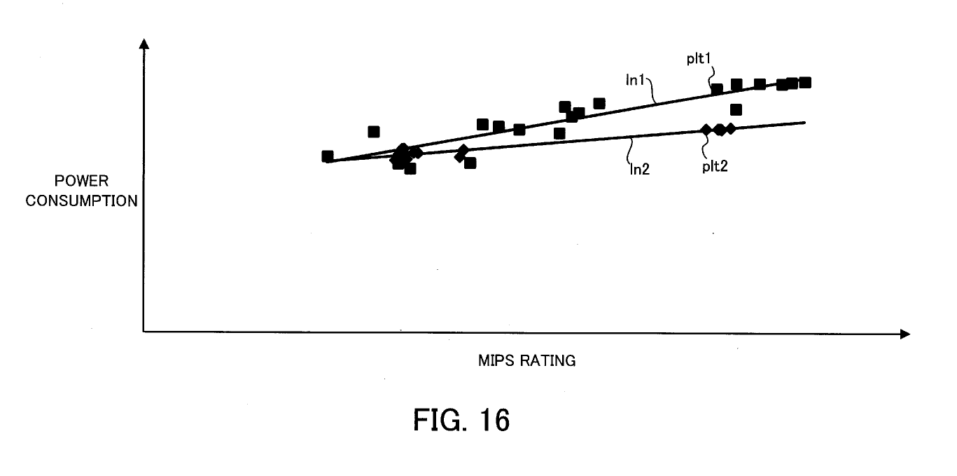

On the other hand, predicting the power consumption by type of instruction (i.e., integer-type instructions versus floating-point-type instructions) reveals good correlations between the MIPS ratings and the power consumption as illustrated below. FIG. 16 illustrates a simulation example of instruction type-specific correlations between the MIPS ratings and the power consumption.

The horizontal axis represents the MIPS rating and the vertical axis represents the power consumption. Each of the black squares (for example, plt1) indicates an example of power calculated using a floating-point benchmark program, and each of the black rhombuses (plt2) indicates an example of power calculated using an integer benchmark program. FIG. 16 presents calculated power consumption results, each specific to one of the two instruction types (i.e., integer and floating-point instruction types), obtained using two types of benchmark programs. The floating-point benchmark program evaluates the floating-point arithmetic performance of the processor. An example of the floating-point benchmark program is LINPACK. The integer benchmark program evaluates the integer arithmetic performance of the processor. An example of the integer benchmark program is Dhrystone.

As illustrated in FIG. 16, there are relatively good instruction type-specific correlations between the power consumption and the MIPS ratings, and their relationships are nearly approximated by straight lines ln1 and ln2 (each having a coefficient of determination close to 1).

The strength of the correlation between the power consumption and the MIPS ratings also varies depending on the type of power consuming factor (the type of cell) in the processor. For example, the correlation between the MIPS ratings and the power consumption for flip-flops (FF) (here, latch circuits are included) is illustrated as follows.

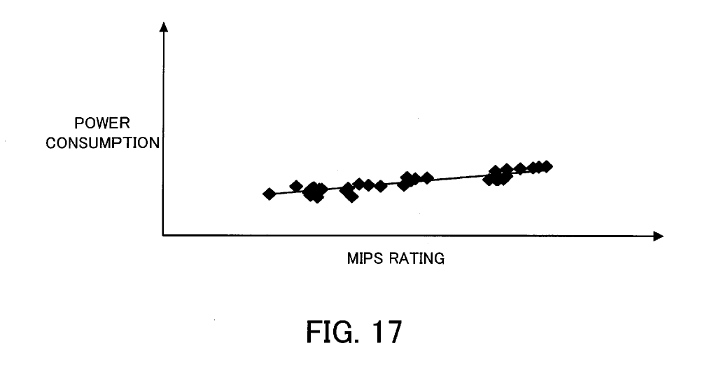

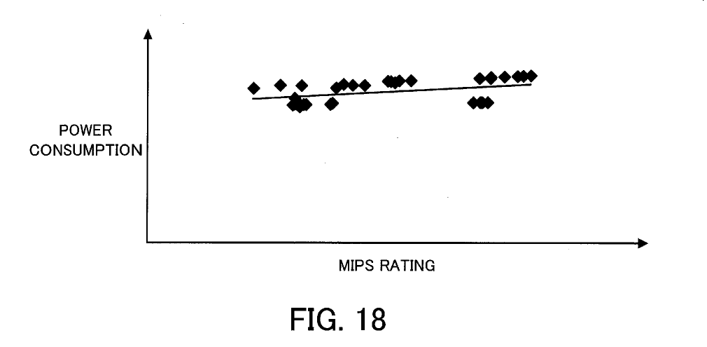

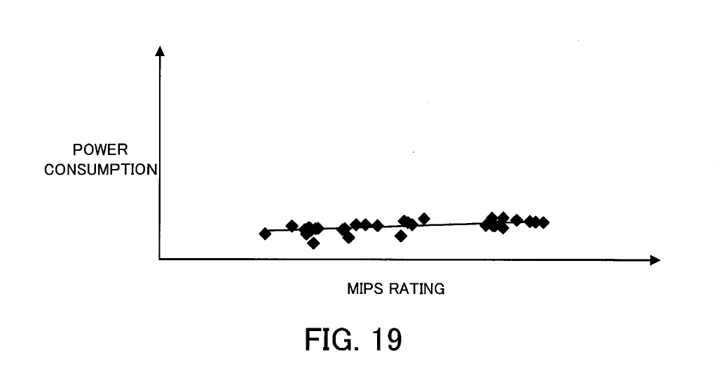

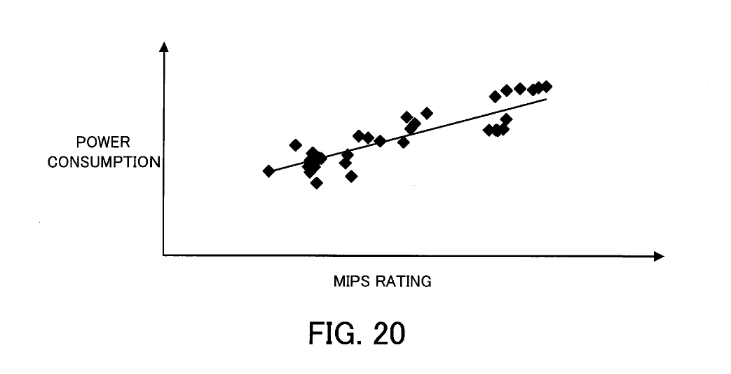

FIG. 17 illustrates a simulation example of the correlation between the MIPS ratings and the power consumption for flip-flops. FIG. 18 illustrates a simulation example of the correlation between the MIPS ratings and the power consumption for clock line-associated cells. FIG. 19 illustrates a simulation example of the correlation between the MIPS ratings and the power consumption for memory (random access memory (RAM)). FIG. 20 illustrates a simulation example of the correlation between the MIPS ratings and the power consumption for other power consuming factors (mainly combinational logic gates).

In FIGS. 17 to 20, the horizontal axis represents the MIPS rating and the vertical axis represents the power consumption. An integer benchmark program and a floating-point benchmark program are used for the simulations. As illustrated in FIG. 17, the power consumption of the flip-flops has a relatively good correlation with the MIPS ratings. On the other hand, as for both the clock line-associated cells (for example, clock buffers) and the memory, there is a rather poor correlation between the power consumption and the MIPS ratings, as illustrated in FIGS. 18 and 19. As for the other power consuming factors, there is a loose correlation between the power consumption and the MIPS ratings, as illustrated in FIG. 20.

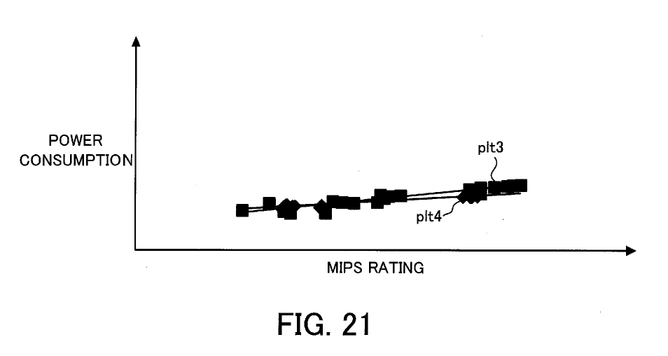

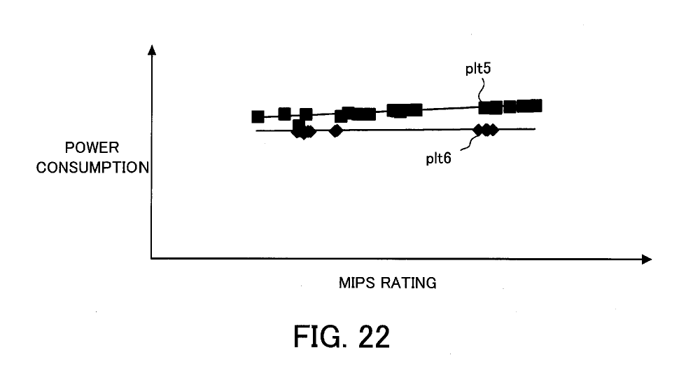

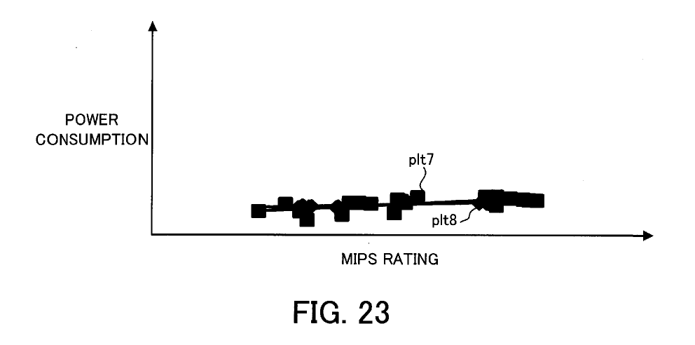

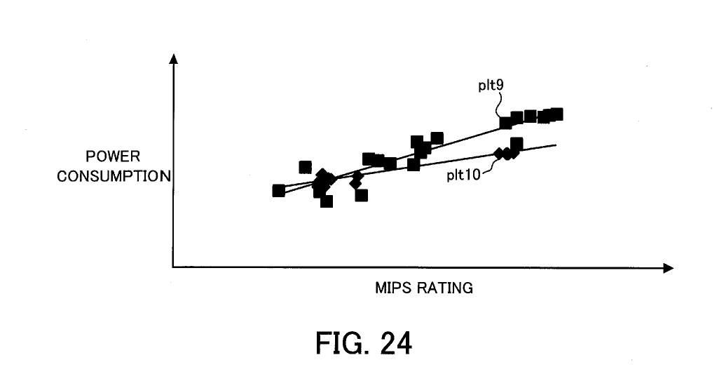

Note that the following results are obtained for each type of the power consuming factors above when the correlation between the power consumption and the MIPS ratings is investigated by type of instruction. FIG. 21 illustrates a simulation example of instruction type-specific correlations between the MIPS ratings and the power consumption for the flip-flops. FIG. 22 illustrates a simulation example of instruction type-specific correlations between the MIPS ratings and the power consumption for the clock line-associated cells. FIG. 23 illustrates a simulation example of instruction type-specific correlations between the MIPS ratings and the power consumption for the memory. FIG. 24 illustrates a simulation example of instruction type-specific correlations between the MIPS ratings and the power consumption for the other power consuming factors.

In FIGS. 21 to 24, the horizontal axis represents the MIPS rating and the vertical axis represents the power consumption. An integer benchmark program and a floating-point benchmark program are individually used for the simulations of the corresponding instruction types. Also in FIGS. 21 to 24, each of the black squares (for example, plt3, plt5, plt7, and plt9) indicates an example of power calculated using the floating-point benchmark program, and each of the black rhombuses (plt4, plt6, plt8, and plt10) indicates an example of power calculated using the integer benchmark program.

As illustrated in FIG. 21, the power consumption of the flip-flops and the MIPS ratings correlate even better when the correlations are calculated by instruction type. As for the clock line-associated cells, the power consumption and the MIPS ratings correlate with each other when examined by instruction type, as illustrated in FIG. 22. As for the memory, the power consumption and the MIPS ratings correlate partially when examined by instruction type, as illustrated in FIG. 23. As for the other power consuming factors, the power consumption and the MIPS ratings correlate relatively well when examined by instruction type, as illustrated in FIG. 24. Note that, as for the clock line-associated cells and the memory, the rate of change of the power consumption with respect to the MIPS ratings is small, as illustrated in FIGS. 22 and 23.

The power estimation method of the fourth embodiment takes account of the above-described instruction types and power consuming factors in creating a power model. Estimated power calculated by the power model is expressed as the sum of power estimated for each classification of the power consuming factors. In addition, the power estimated for each classification of the power consuming factors is obtained using one of the following: the constant; a linear equation with the sum of MIPS ratings as the parameter; and a linear equation with instruction type-specific MIPS ratings as the parameters.

The power model is expressed, for example, as equation (3) below.

$$Pest ( {MIPS}_{Int} , {MIPS}_{FP} ) = {\sum }_{p \_ type ∈ \{ FF , CKBUF , MEM , OTHER \}} {Pest}_{p \_ type} ( {MIPS}_{Int} , {MIPS}_{FP} ) \qquad ( 3 )$$

In equation (3), MIPS_{Int} is an integer-type instruction MIPS rating, MIPS_{FP} is a floating-point-type instruction MIPS rating, p_typeε{FF, CKBUF, MEM, OTHER} indicates classifications of power consuming factors. Individual elements of the set {FF, CKBUF, MEM, OTHER} are flip-flops, clock line-associated cells, memory, and other power consuming factors, respectively.

Pestₚ_{_{—}}_{type}(MIPS_{Int}, MIPS_{FP}) is the power estimated for the classification p_type, and is expressed by three power prediction formulae according to the state of model control variables est_m and est_i, as represented by equation (4) below. That is, as is the case with the power estimation method of the second embodiment, the power prediction formula is expressed by one of the following models: a constant model; a model with a reduced number of parameters; and a model with no number of parameters reduced (a model taking account of the instruction types).

The model control variable est_m is a variable to determine if the power prediction formula (power model) is expressed by the constant or a linear equation. The model control variable est_i is a variable to determine whether to use a different power prediction formula for each instruction type. The model control variables est_m and est_i are determined by processing to be described later.

$${Pest}_{p \_ type} ( {MIPS}_{Int} , {MIPS}_{FP} ) = \{ \begin{matrix}{p}_{p \_ type , const} , & est\_m = const \\ \begin{matrix}{p}_{p \_ type , all} ( \begin{matrix}{MIPS}_{Int} + \\ {MIPS}_{FP}\end{matrix} ) + \\ {p}_{p \_ type , const} ,\end{matrix} & est\_m = l\_inst \_num \& est\_i = TRUE \\ \begin{matrix}{p}_{p \_ type , Int} {MIPS}_{Int} + \\ \begin{matrix}{p}_{p \_ type , FP} {MIPS}_{FP} + \\ {p}_{p \_ type , const} ,\end{matrix}\end{matrix} & est\_m = l\_inst \_num \& est\_i = FALSE\end{matrix} \qquad ( 4 )$$

When est_m=const, Pestₚ_{_{—}}_{type}(MIPS_{Int}, MIPS_{FP}) is pₚ_{_{—}}_{type}, const pₚ_{_{—}}_{type}, const is the constant. When est_m=l_inst_num and est_i=TRUE, Pestₚ_{_{—}}_{type}(MIPS_{Int}, MIPS_{FP}) is expressed by a linear equation with the sum of MIPS ratings of the individual instruction types as the parameter. When est_m=l_inst_num and est_i=FALSE, Pestₚ_{_{—}}_{type} (MIPS_{Int}, MIPS_{FP}) is expressed by a linear equation with MIPS ratings of the individual instruction types as the parameters.

In equation (4), assume that π(est_, p_type, i_type)=pₚ_{_{—}}_{type, Φest}_{_{—}}ᵢ₍ᵢ_{_{—}}_{type)}. Here, i_type indicates an instruction type, and there are two instruction types, Int (integer instruction type) and FP (floating-point instruction type). In addition, Φest_i(i_type) is a function that takes i_type when est_i=TRUE and takes “all” when est_i≠TRUE. In addition, by introducing a function ν(est_m, i_type) that takes a value of 1 when est_m=const and takes MIPSᵢ_{_{—}}_{type} when est_m=l_inst_num into equation (4), equation (4) is rewritten as equation (5) below.

$${Pest}_{p \_ type} ( {MIPS}_{Int} , {MIPS}_{FP} ) = \{ \begin{matrix}0 \times 1 + 0 \times 1 + {p}_{p \_ type , const} , & est\_m = const \\ \begin{matrix}\begin{matrix}{p}_{p \_ type , all} \times {MIPS}_{Int} + \\ {p}_{p \_ type , all} \times {MIPS}_{FP} +\end{matrix} \\ {p}_{p \_ type , const} ,\end{matrix} & est\_m = l\_inst \_num \& est\_i = TRUE \\ \begin{matrix}\begin{matrix}{p}_{p \_ type , Int} \times {MIPS}_{Int} + \\ {p}_{p \_ type , FP} \times {MIPS}_{FP} +\end{matrix} \\ {p}_{p \_ type , const } ,\end{matrix} & est\_m = l\_inst \_num \& est\_i = FALSE\end{matrix} = π ( {est\_i}_{p \_ type} , p\_type , Int ) v ( {est\_m}_{p \_ type} , Int ) + π ( {est\_i}_{p \_ type} , p\_type , FP ) v ( {est\_m}_{p \_ type} , FP ) + {p}_{p \_ type , const} = ( \begin{matrix}{\sum }_{i \_ type ∈ \{ Int , FP \}} π ( {est\_i}_{p \_ type} , p\_type , i\_type ) \\ v ( {est\_m}_{p \_ type} , i\_type )\end{matrix} ) + {p}_{p \_ type , const} \qquad ( 5 )$$

In equation (5), est_i=TRUE when est_m=const, and at that time, Pₚ_{_{—}}_{type, all}=0.

By plugging equation (5) into equation (3), equation (3) is rewritten as equation (6) below.

$$Pest ( {MIPS}_{Int} , {MIPS}_{FP} ) = {\sum }_{p \_ type ∈ \{ FF , CKBUF , MEM , OTHER \}} \{ \begin{matrix}( \begin{matrix}{\sum }_{i \_ type ∈ \{ Int , FP \}} π ( \begin{matrix}\begin{matrix}{est\_i}_{p \_ type} , \\ p\_type ,\end{matrix} \\ i\_type\end{matrix} ) \\ v ( {est\_m}_{p \_ type} , i\_type )\end{matrix} ) + \\ {p}_{p \_ type , const}\end{matrix} \} = {\sum }_{{p \_ type ∈ \{ FF , CKVUF , MEM , OTHER \}}_{i \_ type \{ Int , Fp \}}} π ( {est\_i}_{p \_ type} , p\_type , i\_type ) v ( {est\_m}_{p \_ type} , i\_type ) + ( {\sum }_{p \_ type ∈ \{ FF , CKBUF , MEM , OTHER \}} {p}_{p \_ type , const} ) \qquad ( 6 )$$

In equation (6), equation (7) below is defined.

$${p}_{cosnt} = {\sum }_{p \_ type ∈ \{ FF , CKBUF , MEM , OTHER \}} {p}_{p \_ type , const} \qquad ( 7 )$$

Herewith, equation (8) below is obtained.

$$Pest ( {MIPS}_{Int} , {MIPS}_{FP} ) = ( \begin{matrix}{\sum }_{{p \_ type ∈ \{ FF , CKBUF , MEM , OTHER )}_{i \_ type ∈ \{ Int , FP \}}} π ( {est\_i}_{p \_ type} , p\_type , i\_type ) \\ v ( {est\_m}_{p \_ type} , i\_type )\end{matrix} ) + {p}_{const} \qquad ( 8 )$$

According to the fourth embodiment, the processor 21 acquires input data including parameter values (MIPS ratings) and power values, and calculates the above-described model control variables est_m and est_i, coefficient pₚ_{_{—}}_{type, i}_{_{—}}_{type}, and constant p_{const} based on the input data by regression analysis and tests.

The power estimation method of the fourth embodiment has the same processing flow as that illustrated in FIG. 3. Note however that the power estimation method of the fourth embodiment uses MIPS ratings as the parameter values. Next described is an example of a method of acquiring the input data including MIPS ratings and power values.

(Input Data Acquisition Method)

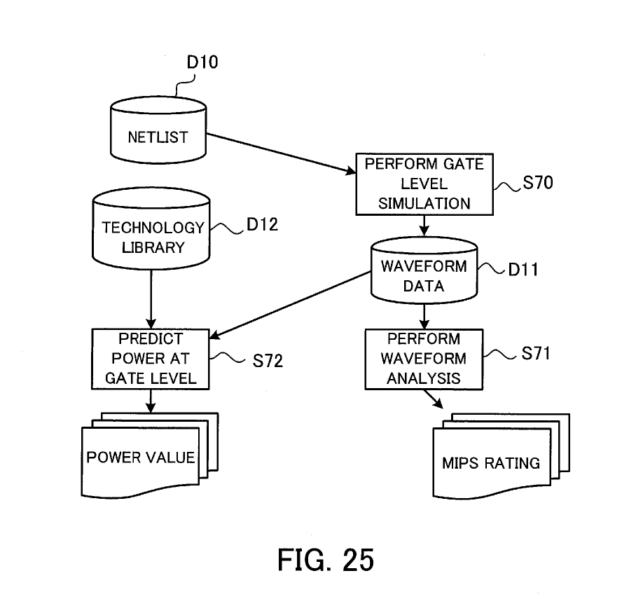

FIG. 25 illustrates an example of an input data acquisition method. For example, when the processor 21 executes a program to create a power library, a gate level simulation is performed using, as an input, a netlist D10 of a semiconductor integrated circuit which is a target of power estimation (step S70). Assume here that the estimation target semiconductor integrated circuit has been physically designed (for example, a prototype chip or the like has been created) so as to allow power calculation.

By the gate level simulation, waveform data D11 at the gate level is obtained. The processor 21 performs waveform analysis based on the waveform data D11 to thereby calculate MIPS ratings (step S71). In addition, using a technology library D12 and the waveform data D11, the processor 21 predicts power at the gate level to thereby calculate power values (step S72). In the calculation of the MIPS ratings and power values, a floating-point benchmark program and an integer benchmark program are used.

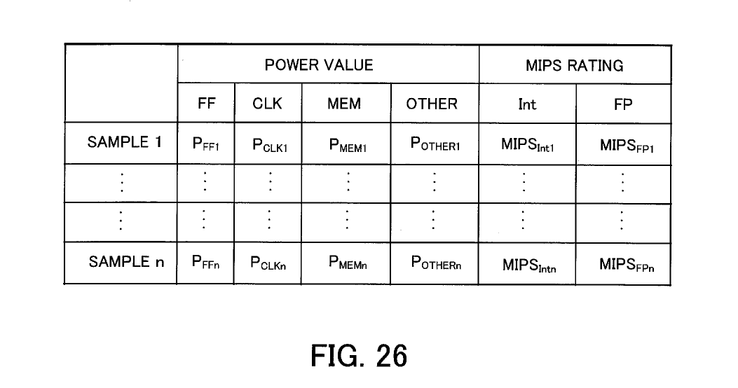

FIG. 26 illustrates an example of calculated power values and MIPS ratings. In FIG. 26, power values and MIPS ratings are listed for each sample. A power value is calculated for each of classification groups consisting of flip-flops (FF), clock line-associated cells (CLK), memory (MEM), and others (OTHER). For example, the following are calculated for Samples 1 to n: power values P_{FF1} to P_{FFn} of the flip-flop group; power values P_{CLK1} to P_{CLKn} of the clock line-associated cell group; power values P_{MEM1} to P_{MEMn} of the memory group; and power values P_{OTHER1} to P_{OTHERn} of the others group. The MIPS ratings are calculated separately for the integer instruction type (Int) and the floating-point instruction type (FP). For example, the following are calculated for Samples 1 to n: integer instruction-type MIPS ratings MIPS_{Int1} to MIPS_{Intn}; and floating-point instruction-type MIPS ratings MIPS_{FP1} to MIPS_{FPn}. The calculated power values and MIPS ratings are stored in a memory unit such as the HDD 23.

Subsequently, the processor 21 acquires (reads) the power values and instruction type-specific MIPS ratings, for example, from the HDD 23 to create a power library. In this regard, the processor 21 may acquire a different parameter of Samples 1 to n.

(Power Library Creation Processing)

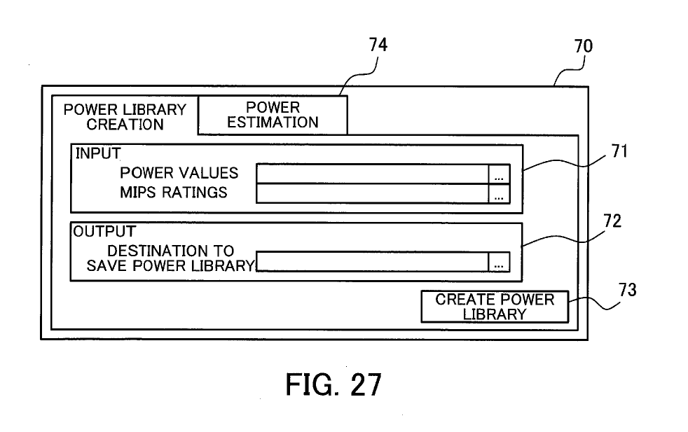

Next described is an example of power library creation processing of the power estimation method according to the fourth embodiment. FIG. 27 illustrates an example of a start screen of power library creation processing. On a screen 70, the user designates a file, including power values and MIPS ratings of samples, in an input file designation section 71. According to the example of FIG. 27, files are designated separately for power values and for MIPS ratings in the input file designation section 71. In addition, the user designates the destination of a power library to be created in a power library saving destination designation section 72. Note that a file including parameter values other than MIPS ratings may be designated. When a button 73 is pressed by the user operating the mouse 25b or the like, power library creation processing described below is carried out. When a tab 74 is pressed by the user operating the mouse 25b or the like, power estimation processing to be described later is carried out.

In the power library creation processing, the processor 21 calculates the model control variables est_mₚ_{_{—}}_{type}, est_iₚ_{_{—}}_{type}, the coefficient pₚ_{_{—}}_{type, i}_{_{—}}_{type}, and the constant p_{const} in equations (3) to (8) above, which are then stored as a power library in a memory unit such as the HDD 23. The model control variable est_mₚ_{_{—}}_{type} is a variable to determine whether the power prediction formula (power model) is expressed by the constant or a linear equation. The model control variable est_mₚ_{_{—}}_{type} is calculated, for example, using the coefficient of determination of regression analysis or a test of the partial regression coefficient.

A method of using the coefficient of determination to calculate the model control variable est_mₚ_{_{—}}_{type} is described first. The processor 21 runs regression analysis using a regression equation like equation (9) below, for example, based on the power values and MIPS ratings illustrated in FIG. 26.

pₚ_{_{—}}_{type,Int}MIPS_{Int}+pₚ_{_{—}}_{type,FP}MIPS_{FP}+pₚ_{_{—}}_{type,const}=Pₚ_{_{—}}_{type} (9)

By the regression analysis, the coefficient pₚ_{_{—}}_{type, i}_{_{—}}_{type} (pₚ_{_{—}}_{type, int} and pₚ_{_{—}}_{type, FP}) and the constant p_{const} are calculated for each classification p_type (for example, the flip-flop group, the clock line-associated cell group, the memory group, and the others group).

Then, the processor 21 calculates the coefficient of determination of the regression analysis. For example, if the coefficient of determination is 0.5 or more, the processor 21 considers that the power consumption of the classification p_type has a strong correlation with the MIPS ratings, and sets the model control variable est_mₚ_{_{—}}_{type} as est_mₚ_{_{—}}_{type}=l_inst_num to express the power prediction formula by a linear equation. On the other hand, if the coefficient of determination is less than 0.5, the processor 21 determines that the power consumption of the classification p_type has a poor correlation with the MIPS ratings, and sets the model control variable est_mₚ_{_{—}}_{type} as est_mₚ_{_{—}}_{type}=const to express the power prediction formula by the constant.

As another method of calculating the model control variable est_mₚ_{_{—}}_{type}, a test of the partial regression coefficient may be employed. When using a test of the partial regression coefficient, the processor 21 runs regression analysis and a test of the partial regression coefficient on equation (10) below where ξ=MIPS_{Int}+MIPS_{FP}, and ζ=MIPS_{FP}.

pₚ_{_{—}}_{type,ξ}ξ+pₚ_{_{—}}_{type,ζ}ζ+pₚ_{_{—}}_{type,const}=Pₚ_{_{—}}_{type} (10)

Note that, in equation (10), pₚ_{_{—}}_{type, ξ}=pₚ_{_{—}}_{type, Int} and pₚ_{_{—}}_{type, ζ}=pₚ_{_{—}}_{type, FP}−pₚ_{_{—}}_{type, Int}.

If both ξ and ζ are found in the test to be insignificant (for example, each significance probability is less than or equal to a reference value), the processor 21 determines that the power consumption of the classification p_type has a poor correlation with the MIPS ratings, and sets the model control variable est_mₚ_{_{—}}_{type} as est_mₚ_{_{—}}_{type}=const to express the power prediction formula by the constant. If at least one of ξ and ζ is found to be significant, the processor 21 determines that the power consumption of the classification p_type has a strong correlation with the MIPS ratings, and sets the model control variable est_mₚ_{_{—}}_{type} as est_mₚ_{_{—}}_{type}=l_inst_num to express the power prediction formula by a linear equation.

Note that the coefficient of variation CV, defined as the ratio of the standard deviation of the power values to its mean, may be used together to calculate the model control variable est_mₚ_{_{—}}_{type}. For example, if the coefficient of variation CV is less than a predetermined value, the processor 21 determines that the power consumption of the classification p_type has a poor correlation with the MIPS ratings, and defines the model control variable est_mₚ_{_{—}}_{type} as est_mₚ_{_{—}}_{type}=const to express the power prediction formula by the constant.

On the other hand, the model control variable est_iₚ_{_{—}}_{type} for determining whether to use a different power prediction formula for each instruction type is calculated using, for example, a test of the partial regression coefficient. If there is a difference between the coefficients pₚ_{_{—}}_{type, Int} and pₚ_{_{—}}_{type, FP} in equation (9) above, the processor 21 sets the model control variable est_iₚ_{_{—}}_{type} as est_iₚ_{_{—}}_{type}=TRUE, considering that the strength of the correlation between the power consumption of the classification p_type and the MIPS ratings differs by instruction type. On the other hand, if there is no difference between the coefficients pₚ_{_{—}}_{type, Int} and pₚ_{_{—}}_{type, FP}, the processor 21 sets the model control variable est_iₚ_{_{—}}_{type} as est_iₚ_{_{—}}_{type}=FALSE, considering that the strength of the correlation between the power consumption of the classification p_type and the MIPS ratings is the same between the instruction types.

In the test, by confirming that pₚ_{_{—}}_{type, ζ}=pₚ_{_{—}}_{type, FP}−pₚ_{_{—}}_{type, Int} is not 0, the coefficients pₚ_{_{—}}_{type, Int} and pₚ_{_{—}}_{type, FP} are determined to be different. In that case, the processor 21 takes, as the null hypothesis, that pₚ_{_{—}}_{type, ζ}=0, and then determines whether a calculated power value falls within the range of “the constant+sampling error”, using the significance probability. When the null hypothesis is rejected, the processor 21 determines that the difference of the power value is not able to be explained by sampling error alone (significant for and sets the model control variable est_iₚ_{_{—}}_{type} as est_iₚ_{_{—}}_{type}=TRUE. When the null hypothesis is not rejected, the processor 21 determines that the difference of the power value is able to be explained by sampling error, and sets the model control variable est_iₚ_{_{—}}_{type} as est_iₚ_{_{—}}_{type}=FALSE.

The coefficient pₚ_{_{—}}_{type, i}_{_{—}}_{type} is calculated according to the model control variable est_iₚ_{_{—}}_{type} in the following manner. When est_iₚ_{_{—}}_{type}=TRUE, the coefficient pₚ_{_{—}}_{type, i}_{_{—}}_{type} is calculated as pₚ_{_{—}}_{type, Int}=pₚ_{_{—}}_{type, ξ} and pₚ_{_{—}}_{type, FP}=pₚ_{_{—}}_{type, ξ}+pₚ_{_{—}}_{type, ζ}. When est_iₚ_{_{—}}_{type}=FALSE, the coefficient pₚ_{_{—}}_{type, i}_{_{—}}_{type} is calculated anew as a coefficient of a power prediction formula pₚ_{_{—}}_{type, allξ}+pₚ_{_{—}}_{type, const}=pₚ_{_{—}}_{type}, which uses only ξ=MIPS_{Int}+MIPS_{FP} as the parameter. Note that pₚ_{_{—}}_{type, all} may be defined as: pₚ_{_{—}}_{type, all}=pₚ_{_{—}}_{type, ξ}. The constant p_{const} is calculated by equation (7) above.

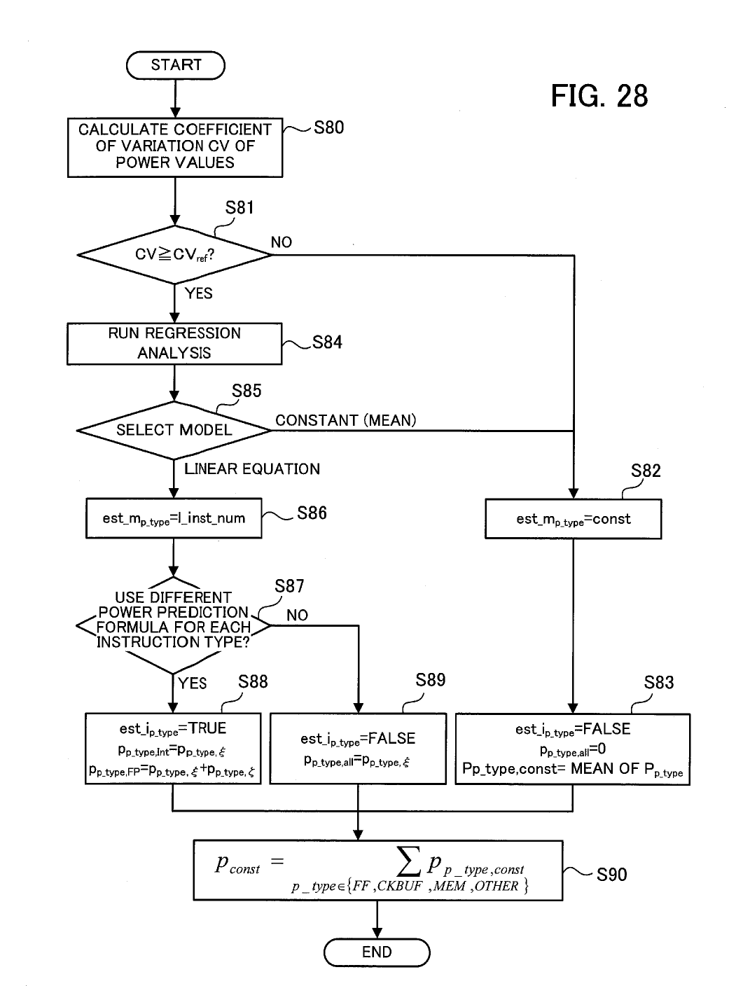

Next, the flow of the power library creation processing for calculating the model control variables est_mₚ_{_{—}}_{type} and est_iₚ_{_{—}}_{type}, the coefficient pₚ_{_{—}}_{type, i}_{_{—}}_{type}, and the constant p_{const} is summarized using a flowchart. FIG. 28 is a flowchart illustrating an exemplified flow of the power library creation processing. Note that the sequence of individual processing steps is just an example, and the order of the processing steps may be changed accordingly. The processor 21 performs the following steps S80 to S89 for each classification p_type (for example, each of the flip-flop group, the clock line-associated cell group, the memory group, and the others group).

First, the processor 21 calculates the coefficient of variation CV of the power values (step S80), and then determines whether the coefficient of variation CV is more than or equal to a reference value CV_{ref} (for example, 0.1) (step S81). When having determined that CV≧CV_{ref} is not satisfied, the processor 21 sets the model control variable est_mₚ_{_{—}}_{type} as est_mₚ_{_{—}}_{type}=const (step S82). Herewith, while the model control variable est_iₚ_{_{—}}_{type} is set as est_iₚ_{_{—}}_{type}=FALSE, the coefficient pₚ_{_{—}}_{type, all} is 0, and pₚ_{_{—}}_{type, const} is the mean of the power values Pₚ_{_{—}}_{type} (step S83). As a result, the power prediction formula for the classification p_type is modeled by the constant (the mean of the power values pₚ_{_{—}}_{type}).

On the other hand, when having determined CV≧CV_{ref} in step S81, the processor 21 runs regression analysis (step S84). In step S84, the processor 21 calculates, for example, the coefficient of determination, the coefficients pₚ_{_{—}}_{type, ξ} and pₚ_{_{—}}_{type, ζ}, and the constant pₚ_{_{—}}_{type, const}, as described above.

Subsequently, the processor 21 selects a model (step S85). In step S85, the processor 21 determines whether to model the power prediction formula by the constant (the mean) or a linear equation. As described above, if the coefficient of determination is, for example, 0.5 or more, the processor 21 considers that the power consumption has a strong correlation with the MIPS ratings, and determines to model the power prediction formula by a linear equation. If the coefficient of determination is less than 0.5, the processor 21 considers that the power consumption has a poor correlation with the MIPS ratings, and determines to model the power prediction formula by the constant.

In addition, in the case of using a test of the partial regression coefficient to select a model, the processor 21 considers that the power consumption has a poor correlation with the MIPS ratings if both and are insignificant, and determines to model the power prediction formula by the constant, as described above. On the other hand, if at least one of ξ and ζ is significant, the processor 21 considers that the power consumption has a strong correlation with the MIPS ratings, and determines to model the power prediction formula by a linear equation.

When having determining in step S85 to model the power prediction formula by the constant (the mean), the processor 21 proceeds to step S82 described above. On the other hand, when having determined to model the power prediction formula by a linear equation, the processor 21 sets the model control variable est_mₚ_{_{—}}_{type} as est_mₚ_{_{—}}_{type}=l_inst_num (step S86).

Subsequently, the processor 21 determines whether to use a different power prediction formula for each instruction type (integer instruction type and floating-point instruction type) (step S87). In step S87, the processor 21 runs a test of the partial regression coefficient described above, and determines to use a different power prediction formula for each instruction type when the test result indicates that the difference in power values between the instruction types is not able to be explained by sampling error alone (significant for ζ). On the other hand, the processor 21 determines not to use different power prediction formulae according to the instruction types when the test result indicates that the difference in the power values is able to be explained by sampling error (insignificant for

When having determined to use a different power prediction formula for each instruction type, the processor 21 sets the model control variable est_iₚ_{_{—}}_{type} and the coefficients pₚ_{_{—}}_{type, Int} and pₚ_{_{—}}_{type, FP} as follows: est_iₚ_{_{—}}_{type}=TRUE; pₚ_{_{—}}_{type, Int}=pₚ_{_{—}}_{type, ξ}; and pₚ_{_{—}}_{type, FP}=pₚ_{_{—}}_{type,} ξ+pₚ_{_{—}}_{type, ζ} (step S88). When having determined not to use different power prediction formulae according to the instruction types, the processor 21 sets the model control variable est_iₚ_{_{—}}_{type} and the coefficient pₚ_{_{—}}_{type, all} as follows: est_iₚ_{_{—}}_{type}=FALSE; and pₚ_{_{—}}_{type, all}=pₚ_{_{—}}_{type, ξ} (step S89). Note that, instead of the coefficient pₚ_{_{—}}_{type, ξ}, the coefficient pₚ_{_{—}}_{type, all} of the power prediction formula pₚ_{_{—}}_{type, allξ}+pₚ_{_{—}}_{type, const}=pₚ_{_{—}}_{type}, which uses only ξ=MIPSᵢₙₜ+MIPS_{FP} as the parameter, may be used as described above.

After the above-described processing is carried out for each classification p_type, the constant p_{const} is calculated based on equation (7) above (step S90).

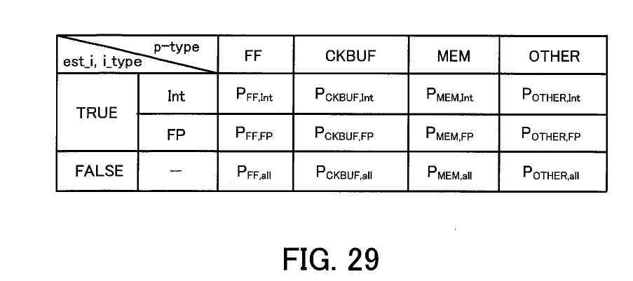

The model control variables est_mₚ_{_{—}}_{type} and est_iₚ_{_{—}}_{type}, the coefficient pₚ_{_{—}}_{type, i}_{_{—}}_{type}, and the constant p_{const} calculated in the above-described manner are then stored, for example, in the HDD 23 as a power library. FIG. 29 illustrates an example of a power library. According to the power library exemplified in FIG. 29, specific values of the coefficient pₚ_{_{—}}_{type, i}_{_{—}}_{type} are arranged in a table-like manner based on the model control variable est_i, i_type (Int (integer instruction type) and FP (floating-point instruction type)) and the classifications p_type. p_{FF, Int}, p_{CKBUF, Int}, p_{MEM, Int}, and p_{OTHER, Int} are values of the coefficient pₚ_{_{—}}_{type, i}_{_{—}}_{type} when the model control variable est_i is TRUE and i_type is Int. p_{FF, FP}, p_{CKBUF, FP}, p_{MEM, FP}, and p_{OTHER, FP} are values of the coefficient pₚ_{_{—}}_{type, i}_{_{—}}_{type} when the model control variable est_i is TRUE and i_type is FP. p_{FF, all}, p_{CKBUF, all}, p_{MEM, all}, and p_{OTHER, all} are values of the coefficient pₚ_{_{—}}_{type, i}_{_{—}}_{type} when the model control variable est_i is FALSE.

(Power Estimation Processing)

Next described is an example of power estimation processing of the power estimation method according to the fourth embodiment.

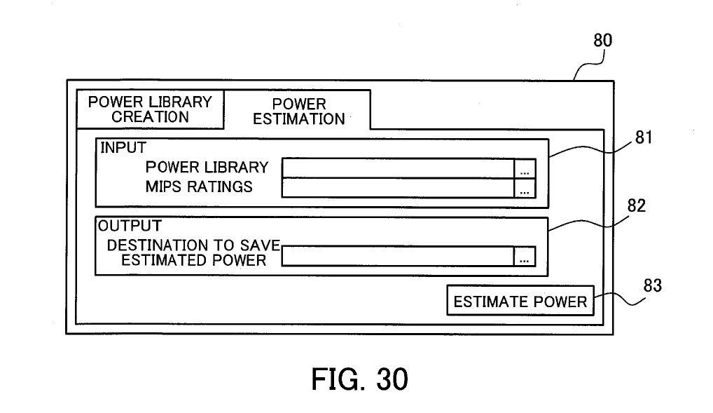

FIG. 30 illustrates an example of a start screen of power estimation processing. On a screen 80, the user designates files, including a power library and MIPS ratings, in an input file designation section 81. Note that the MIPS ratings may be the same as or different from those input when the power library was created. The MIPS ratings are acquired, for example, from simulations using an instruction set simulator (ISS), electronic system level (ESL) simulations, or performance analysis information provided by processors.

The user also designates the destination of estimated power to be calculated in an estimated power saving destination designation section 82. When a button 83 is pressed by the user operating the mouse 25b or the like, power estimation processing described below is carried out.

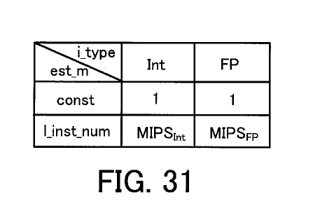

In the power estimation processing, the processor 21 calculates estimated power Pest(MIPS_{Int}, MIPS_{FP}) based on equation (8), with reference to the input MIPS ratings (MIPS_{Int}, MIPS_{FP}) and power library. Note that, in equation (8), π(est_iₚ_{_{—}}_{type}, p_type, i_type) is a value of the coefficient pₚ_{_{—}}_{type, i}_{_{—}}_{type} of a power library like one illustrated in FIG. 29. In addition, in equation (8), a parameter value ν(est_mₚ_{_{—}}_{type}, i_type) is determined, for example, based on the following table. FIG. 31 illustrates an example of a table for designating a parameter value. According to the table exemplified in FIG. 31, parameter values used as ν(est_mₚ_{_{—}}_{type}, i_type) are arranged based on the model control variable est_m (const and l_inst_num) and the instruction type i_type (Int and FP). When the model control variable est_m is const, the value of ν(est_mₚ_{_{—}}_{type}, i_type) is 1 regardless of the instruction type i_type. When the model control variable est_m is l_inst_num, the value of ν(est_mₚ_{_{—}}_{type}, i_type) is the input MIPS_{Int} if the instruction type i_type is Int and the input MIPS_{FP} if the instruction type i_type is FP.

The processor 21 applies a value from the power library and a value from the table designating parameter values illustrated in FIG. 31 to the power model expressed by equation (8) to thereby calculate estimated power.

(Modification of Power Library Creation Processing)

Next described is a modification of the power library creation processing. In equation (5) above, Pestₚ_{_{—}}_{type} (MIPS_{Int}, MIPS_{EP})=0×1+0×1+pₚ_{_{—}}_{type, const} adopted when est_m=const is the same if it is defined as 0×MIPS_{Int}+0×MIPS_{FP}+pₚ_{_{—}}_{type, const}. In addition, according to equation (5), when est_m=const (i.e., when the power prediction formula is modeled by the constant), pₚ_{_{—}}_{type, Int} and pₚ_{_{—}}_{type, FP} are 0. When est_m=l_inst_num and est_i=TRUE (when the power prediction formula is modeled by a linear equation and a different power prediction formula is used for each instruction type), pₚ_{_{—}}_{type, Int} and pₚ_{_{—}}_{type, FP} are pₚ_{_{—}}_{type, all}. By creating a power library based on this information and using the power library in the power estimation processing, equation (5) is simplified as equation (11) below.

Pestₚ_{_{—}}_{type}(MIPS_{Int},MIPS_{FP})=pₚ_{_{—}}_{type,Int}×MIPS_{Int}+pₚ_{_{—}}_{type,FP}×MIPS_{FP}+pₚ_{_{—}}_{type,const} (11)

As a result, the power prediction formula need not use the coefficient pₚ_{_{—}}_{type, all}, the model control variables est_iₚ_{_{—}}_{type} and est_mₚ_{_{—}}_{type}, and the functions π(est_i, p_type, i_type) and ν(est_m, i_type). Consequently, the power model equation (8) is simplified as equation (12) below.

$$Pest ( {MIPS}_{Int} , {MIPS}_{FP} ) = ( {\sum }_{{p \_ type ∈ \{ FF , CKBUF , MEM , OTHER \}}_{i \_ type ∈ \{ Int , FP \}}} {p}_{p \_ type} , {MIPS}_{i \_ type} ) + {p}_{const} \qquad ( 12 )$$

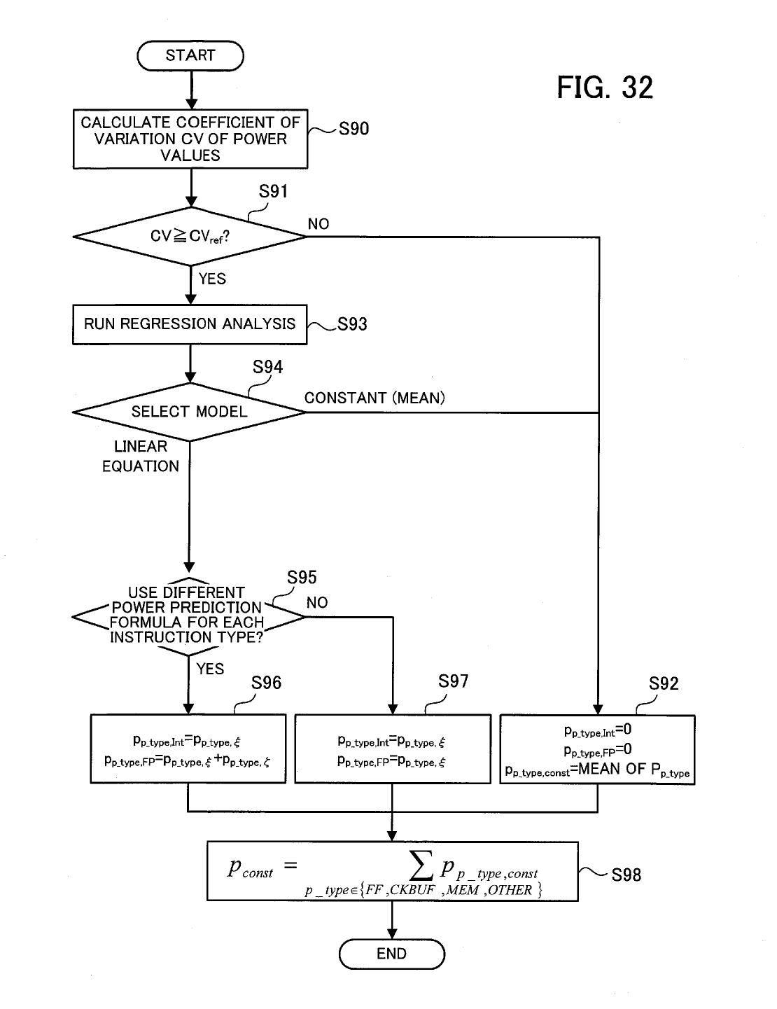

Next described is power library creation processing based on a power model expressed by equation (12) above. FIG. 32 is a flowchart illustrating a modification of the power library creation processing. Note that the sequence of individual processing steps is just an example, and the order of the processing steps may be changed accordingly. The processor 21 performs the following steps S90 to S97 for each classification p_type (for example, each of the flip-flop group, the clock line-associated cell group, the memory group, and the others group).

Steps S90 and S91 are the same as steps S80 and S81, respectively, of FIG. 28. Note however that, because the power library creation processing based on equation (12) does not use the model control variable est_mₚ_{_{—}}_{type}, the processor 21 proceeds to step S92 when having determined that CV≧CV_{ref} is not satisfied, without setting the model control variable est_mₚ_{_{—}}_{type} as est_mₚ_{_{—}}_{type}=const.

In step S92, the processor 21 makes the following definitions: pₚ_{_{—}}_{type, Int}=0; pₚ_{_{—}}_{type, FP}=0; and pₚ_{_{—}}_{type, const}=the mean of pₚ_{_{—}}_{type}.

In steps S93 and S94, the processor 21 runs regression analysis and selects a model to be used, as in steps S84 and S85, respectively, of FIG. 28. Note however that, if determining, in the model selection, to model the power prediction formula by the constant, the processor 21 proceeds to step S92 without setting the model control variable est_mₚ_{_{—}}_{type} as est_mₚ_{_{—}}_{type}=const, as described above. In addition, if determining to model the power prediction formula by a linear equation, the processor 21 proceeds to step S95 without setting the model control variable est_mₚ_{_{—}}_{type} as est_mₚ_{_{—}}_{type}=l_inst_num.

In step S95, the processor 21 runs a test as in step S87 of FIG. 28 to thereby determine whether to use a different power prediction formula for each instruction type (integer instruction type and floating-point instruction type).

When having determined to use a different power prediction formula for each instruction type, the processor 21 proceeds to step S96. On the other hand, when having determined not to use a different power prediction formula for each instruction type, the processor 21 proceeds to step S97. In step S96, the processor 21 sets the coefficients pₚ_{_{—}}_{type, Int} and pₚ_{_{—}}_{type, FP} as pₚ_{_{—}}_{type, Int}=pₚ_{_{—}}_{type, ξ} and pₚ_{_{—}}_{type, FP}=pₚ_{_{—}}_{type, ξ}+pₚ_{_{—}}_{type, ζ}. In step S97, the processor 21 sets the coefficients pₚ_{_{—}}_{type, Int} and pₚ_{_{—}}_{type, FP} as pₚ_{_{—}}_{type, Int}=pₚ_{_{—}}_{type, ξ} and pₚ_{_{—}}_{type, FP}=pₚ_{_{—}}_{type, ξ}.

After the above-described processing is carried out for each classification p_type, the constant const is calculated based on equation (7) above (step S98).

The coefficient pₚ_{_{—}}_{type, i}_{_{—}}_{type} and the constant p_{const} calculated in the above-described manner are then stored, for example, in the HDD 23 as a power library. According to the above-described processing, a power library is created without the coefficient pₚ_{_{—}}_{type, all} and the model control variables est_iₚ_{_{—}}_{type} and est_mₚ_{_{—}}_{type}. Therefore, the power estimation processing need not refer to tables illustrated in FIGS. 29 and 31, and is able to calculate estimated power based on the coefficient pₚ_{_{—}}_{type, i}_{_{—}}_{type}, the constant p_{const}, and the input parameter values (MIPS ratings).

The power estimation method according to the fourth embodiment described above is capable of power estimation in consideration of the instruction types and the power consumption factors, enabling highly accurate estimation of power consumption of a semiconductor integrated circuit including a processor. In addition, in the case where sorting the MIPS ratings by instruction type has less influence on the estimated power consumption, the parameter with instruction type-specific MIPS ratings added together is used. This enables creating a simple power model, and thus the same effect as in the power estimation method of the second or third embodiment may be achieved.

Further, the above-described power library creation processing may be combined with the processing described in FIGS. 4 to 6. Herewith, even when different parameters in addition to the MIPS ratings are used, a simple power model with a reduced number of parameters, or using the mean power, is created in consideration of the power consumption of the processor of the power estimation target apparatus.

### (e) Fifth Embodiment

Next described is a power estimation method according to a fifth embodiment. As for a power estimating apparatus, the power estimating apparatus 20 of FIG. 2 is applicable. The power estimation method of the fifth embodiment is also designed to estimate power consumption of a semiconductor integrated circuit including a processor such as a CPU and a DSP. According to the power estimation method, the power consumption is estimated by creating a power model in consideration of the activity factor of the processor in addition to its power consuming factors and instruction types. The activity factor is the fraction of the switching signals per clock cycle (=(the number of signal switches)/(clock frequency)).

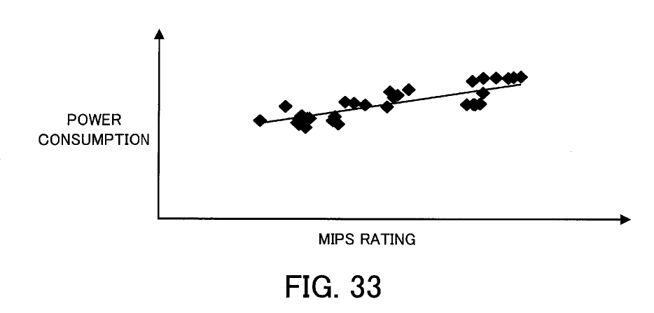

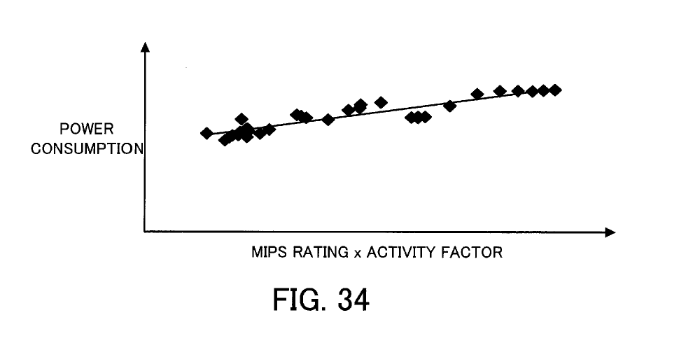

FIG. 33 illustrates a simulation example of the correlation between MIPS ratings and power consumption. In addition, FIG. 34 illustrates a simulation example of the correlation between MIPS ratings multiplied by activity factors and power consumption. In FIG. 33, the horizontal axis represents the MIPS rating and the vertical axis represents the power consumption. In FIG. 34, the horizontal axis represents the MIPS rating multiplied by the activity factor and the vertical axis represents the power consumption. The power consumption of FIGS. 33 and 34 is the sum of power consumption of individual power consuming factors (flip-flops, clock buffers, memory, and others). As for each of the flip-flops and the memory, the average activity factor of its clock terminal is used as the activity factor. As for each of the clock buffers and the other power consuming factors, the average activity factor of its output terminal is used as the activity factor. Note that, in the simulation, a floating-point benchmark program is used for floating-point-type instructions, and an integer benchmark program is used for integer-type instructions. As seen in FIGS. 33 and 34, the MIPS ratings multiplied by the activity factors have a better correlation with the power consumption (FIG. 34) than the MIPS ratings alone (FIG. 33).

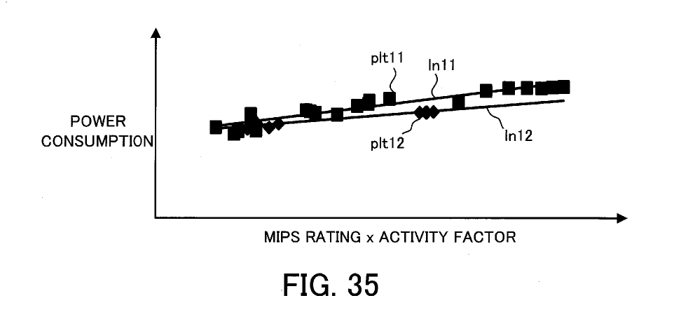

FIG. 35 illustrates a simulation example of instruction type-specific correlations between MIPS ratings multiplied by activity factors and power consumption. The horizontal axis represents the MIPS rating multiplied by the activity factor and the vertical axis represents the power consumption. Each of the black squares (for example, plt11) indicates an example of power calculated using the floating-point benchmark program, and each of the black rhombuses (plt12) indicates an example of power calculated using the integer benchmark program. As for FIG. 35, power consumption for each of the two instruction types (the integer instruction type and floating-point instruction type) is calculated by a corresponding one of the two benchmark programs. Although the power consumption and the MIPS ratings of FIG. 16 have relatively good instruction type-specific correlations, the power consumption and the MIPS ratings multiplied by the activity factors of FIG. 35 have even better instruction type-specific correlations, and their instruction type-specific relationships are almost approximated by lines ln11 and ln12.

According to the power estimation method of the fifth embodiment, a power model is created in consideration of the activity factors described above in addition to the instruction types and the power consuming factors. Estimated power calculated by the power model is expressed as the sum of power estimated for each classification p_type of the power consuming factors. In addition, the power estimated for each classification p_type is obtained using one of the following: the constant; a linear equation with the sum of MIPS ratings (or MIPS ratings multiplied by the activity factors) as the parameter; and a linear equation with MIPS ratings of the individual instruction types (or MIPS ratings of the individual instruction types multiplied by the activity factors) as the parameters. Note that the activity factor applied varies for each classification p_type, but is approximated by one of the activity factor of a clock tree and the activity factor of a data path. Assume in the following that the clock tree activity factor is used for each of the flip-flops, the memory, and the clock buffers which have clock terminals, and the data path activity factor is used for the others. In this manner, the calculated amount is reduced. Note that a value obtained by weighted-averaging the mean activity factor of the flip-flops based on the number of cells in each flip-flop may be used instead of the clock tree activity factor. Similarly, a value obtained by weighted-averaging the mean activity factor of the memory based on the number of cells in each memory element may be used instead. A value obtained by weighted-averaging the mean activity factor of the clock buffers based on the number of cells in each clock buffer may be used instead.

The power model is, for example, expressed as follows.

$$Pest ( {MIPS}_{Int} , {MIPS}_{FP} , {α}_{CK} , {α}_{DP} ) = {\sum }_{p \_ type ∈ \{ FF , CKBUF , MEM , OTHER \}} {Pest}_{p \_ type} ( {MIPS}_{Int} , {MIPS}_{FP} , {α}_{CK} , {α}_{DP} ) \qquad ( 13 )$$

In equation (13), α_{CK} is the clock tree activity factor, and α_{DP} is the data path activity factor. The remaining elements are the same as those in equation (3). Pestₚ_{_{—}}_{type} (MIPS_{Int}, MIPS_{FP}, α_{CK}, α_{DP}) is the power estimated for the classification p_type, and is expressed by five different power prediction formulae according to the state of the model control variables est_m and est_i, as illustrated in equation (14).

$${Pest}_{p \_ type} ( {MIPS}_{Int} , {MIPS}_{FP} , {α}_{CK} , {α}_{DP} ) = \{ \begin{matrix}{p}_{p \_ type , const} , & est\_m = const \\ \begin{matrix}{p}_{p \_ type , all} ( {MIPS}_{Int} + {MIPS}_{FP} ) + \\ {p}_{p \_ type , const} ,\end{matrix} & est\_m = l\_inst \_num \& est\_i = TRUE \\ \begin{matrix}\begin{matrix}{p}_{p \_ type , Int} {MIPS}_{Int} + \\ {p}_{p \_ type , FP} {MIPS}_{FP} +\end{matrix} \\ {p}_{p \_ type , const} ,\end{matrix} & est\_m = l\_inst \_num \& est\_i = FALSE \\ \begin{matrix}{p}_{p \_ type , all} \{ ( {MIPS}_{Int} + {MIPS}_{FP} ) {α}_{p \_ type} \} + \\ {p}_{p \_ type , const}\end{matrix} & est\_m = l\_act \_num \& est\_i = TRUE \\ \begin{matrix}{p}_{p \_ type , Int} ( {MIPS}_{Int} {α}_{p \_ type} ) + \\ {p}_{p \_ type , FP} ( {MIPS}_{FP} {α}_{p \_ type} ) + {p}_{p \_ type , const} ,\end{matrix} & est\_m = l\_act \_num \& est\_i = FALSE\end{matrix} \qquad ( 14 )$$

Equation (14) includes two power prediction formulae taking account of the activity factors in addition to the three power prediction formulae of equation (4). That is, a linear equation is added which represents Pestₚ_{_{—}}_{type} (MIPS_{Int}, MIPS_{FP}, α_{CK}, α_{DP}) when est_m=l_act_num and est_i=TRUE and takes, as the parameter, a value obtained by multiplying the sum of MIPS ratings of the individual instruction types by the activity factor αₚ_{_{—}}_{type}. In addition, a linear equation is added which represents Pestₚ_{_{—}}_{type} (MIPS_{Int}, MIPS_{FP}, α_{CK}, α_{DP}) when est_m=l_act_num and est_i=FALSE and takes, as the parameters, values obtained by multiplying MIPS ratings of the individual instruction types by the activity factor αₚ_{_{—}}_{type}. The activity factor αₚ_{_{—}}_{type} is α_{CK} when the classification p_type is the flip-flop group, the memory group, and the clock buffer group, and α_{DP} when the classification p_type is the others group.

Equation (14) is rewritten as equation (15) below.

$${Pest}_{p \_ type} ( {MIPS}_{Int} , {MIPS}_{FP} , {α}_{CK} , {α}_{DP} ) = \{ \begin{matrix}0 \times {MIPS}_{Int} + 0 \times {MIPS}_{FP} + {p}_{p \_ type , const} , & est\_m = const \\ \begin{matrix}{p}_{p \_ type , all} \times {MIPS}_{Int} + {p}_{p \_ type , all} \times \\ {MIPS}_{FP} + {p}_{p \_ type , const} ,\end{matrix} & est\_m = l\_inst \_num \& est\_i = TRUE \\ \begin{matrix}{p}_{p \_ type , Int} \times {MIPS}_{Int} + {p}_{p \_ type , FP} \times \\ {MIPS}_{FP} + {p}_{p \_ type , const} ,\end{matrix} & est\_m = l\_inst \_num \& est\_i = FALSE \\ \begin{matrix}{p}_{p \_ type , all} \times {MIPS}_{Int} {α}_{p \_ type} + {p}_{p \_ type , all} \times \\ {MIPS}_{FP} {α}_{p \_ type} + {p}_{p \_ type , const} ,\end{matrix} & est\_m = l\_act \_num \& est\_i = TRUE \\ \begin{matrix}{p}_{p \_ type , Int} \times {MIPS}_{Int} {α}_{p \_ type} + {p}_{p \_ type , FP} \times \\ {MIPS}_{FP} {α}_{p \_ type} + {p}_{p \_ type , const} ,\end{matrix} & est\_m = l\_act \_num \& est\_i = FALSE\end{matrix} \qquad ( 15 )$$

In Equation (15), assume that pₚ_{_{—}}_{type, Inst}=0 and pₚ_{_{—}}_{type, FP}=0 when est_m=const, and that pₚ_{_{—}}_{type, Inst}=pₚ_{_{—}}_{type, all} and pₚ_{_{—}}_{type, FP}=pₚ_{_{—}}_{type, all} when est_i=TRUE. In addition, the function ν(est_mₚ_{_{—}}_{type}, i_type) is introduced. The function ν(est_mₚ_{_{—}}_{type}, i_type) is a function that takes MIPSᵢ_{_{—}}_{type}αₚ_{_{—}}_{type} when the model control variable est_m is l_act_num and takes MIPSᵢ_{_{—}}_{type} when the model control variable est_m is other than l_act_num. Equation (15) is rewritten as equation (16) below, using the function ν(est_mₚ_{_{—}}_{type}, i_type).

$${Pest}_{p \_ type} ( {MIPS}_{Int} , {MIPS}_{FP} , {α}_{CK} , {α}_{DP} ) = {p}_{p \_ type , Int} v ( {est\_m}_{p \_ type} , Int ) + {p}_{p \_ type , FP} v ( {est\_m}_{p \_ type} , FP ) + {p}_{p \_ type , const} = ( {\sum }_{i \_ type ∈ \{ Int , FP \}} {p}_{p \_ type , i \_ type} v ( {est\_m}_{p \_ type} , p\_type , i\_type ) ) + {p}_{p \_ type , const} \qquad ( 16 )$$

By plugging equation (16) into equation (13), the following power prediction formula is obtained.

$$Pest ( {MIPS}_{Int} , {MIPS}_{FP} , {α}_{CK} , {α}_{DP} ) = ( {\sum }_{{p \_ type ∈ \{ FF , CKBUF , MEM , OTHER \}}_{i \_ type ∈ \{ Int , FP \}}} {p}_{p \_ type} v ( {est\_m}_{p \_ type} , p\_type , i\_type ) ) + {p}_{const} \qquad ( 17 )$$

According to the power estimation method of the fifth embodiment, the processor 21 calculates the model control variables est_m and est_i, the coefficient pₚ_{_{—}}_{type}, and the constant p_{const} by running regression analysis and tests based on the input data (the MIPS rating MIPSᵢ_{_{—}}_{type}, the activity factor αₚ_{_{—}}_{type}, and power values). The flow of the power estimation method according to the fifth embodiment is the same as one illustrated in FIG. 3. Note however that the power estimation method of the fifth embodiment uses MIPS ratings and activity factors as parameters. Next described is an example of a method of acquiring the input data including MIPS ratings, activity factors, and power values.

(Input Data Acquisition Method)

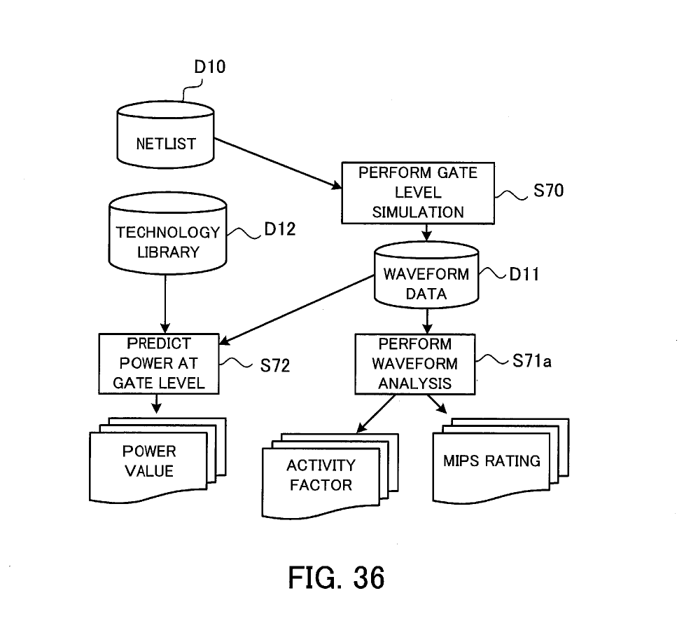

FIG. 36 illustrates an example of an input data acquisition method. Processing steps and data similar to those of FIG. 25 are denoted by like reference numerals, and repeated description thereof is omitted. Assume in the following that an estimation target semiconductor integrated circuit has been physically designed (for example, a prototype chip or the like has been created) so as to allow the processor 21 to calculate the consumption power as well as to acquire the activity factor of each classification p_type. The activity factors used to create a power library are, for example, the mean activity factors of the individual classifications p_type.

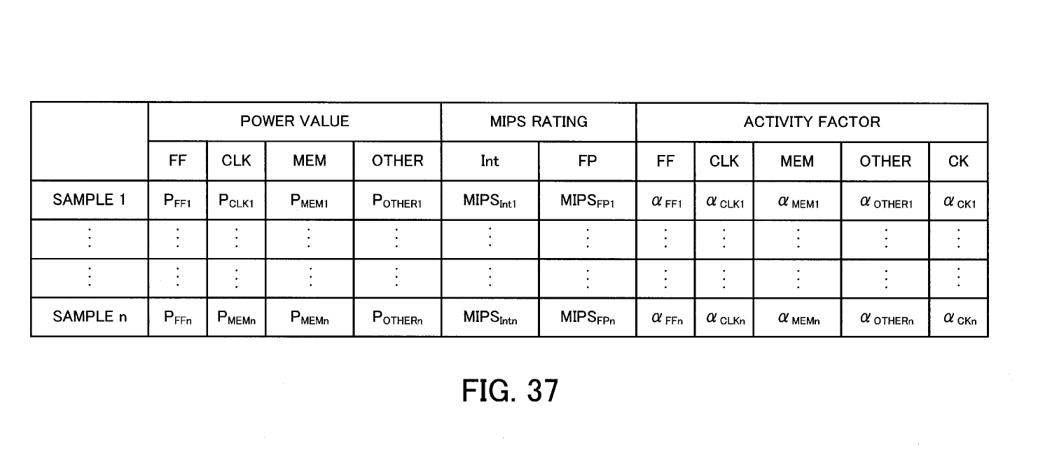

In the power estimation method of the fifth embodiment, at the time of the waveform analysis (step S71a), the processor 21 acquires activity factors, in addition to MIPS ratings, from the waveform data D11. FIG. 37 illustrates an example of calculated power values, MIPS ratings, and activity factors. In FIG. 37, the activity factors are listed for each sample, in addition to the power values and MIPS ratings for each sample illustrated in FIG. 26. The activity factors are sorted according to the individual classification groups consisting of flip-flops (FF), clock line-associated cells (CLK), memory (MEM), others (OTHER), and a clock tree (CK). For example, the following are listed for Samples 1 to n: activity factors α_{FF1} to α_{FFn} of the flip-flop group; activity factors α_{CLK1} to α_{CLKn} of the clock line-associated cell group; activity factors α_{MEM1} to α_{MEMn} of the memory group; activity factors α_{OTHER1} to α_{OTHERn} of the others group; and activity factors α_{CK1} to α_{CKn} of the clock tree group.

The calculated power values, MIPS ratings and activity factors are stored in a memory unit such as the HDD 23. Subsequently, the processor 21 acquires (reads) the power values and MIPS ratings, for example, from the HDD 23 to create a power library.

(Power Library Creation Processing)

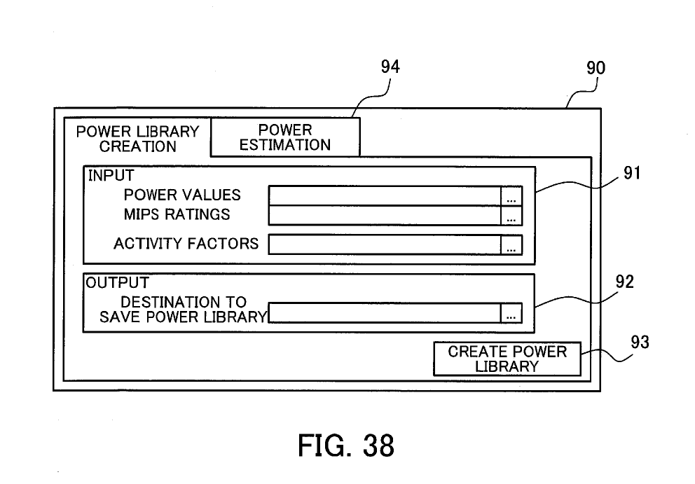

Next described is an example of power library creation processing of the power estimation method according to the fifth embodiment. FIG. 38 illustrates an example of a start screen of power library creation processing. On a screen 90, the user designates a file, including power values, MIPS ratings, activity factors of samples, in an input file designation section 91. According to the example of FIG. 38, files are designated separately for the power values, the MIPS ratings, and the activity factors in the input file designation section 91. In addition, the user designates the destination of a power library to be created in a power library saving destination designation section 92. When a button 93 is pressed by the user operating the mouse 25b or the like, power library creation processing described below is carried out. When a tab 94 is pressed by the user operating the mouse 25b or the like, power estimation processing to be described later is carried out.

The power library creation processing is almost the same as that of the fourth embodiment described above. Note however that the power library creation processing of the fifth embodiment includes the following additional processes due to the introduction of the activity factors. Equation (14) (or equation (15)) includes five power prediction formulae, some of which use and others of which do not use the activity factor αₚ_{_{—}}_{type}. Amongst them, the processor 21 determines which one of the power prediction formulae with or without the activity factor αₚ_{_{—}}_{type} predict the power consumption better. For this determination, the coefficient of determination is used, for example.

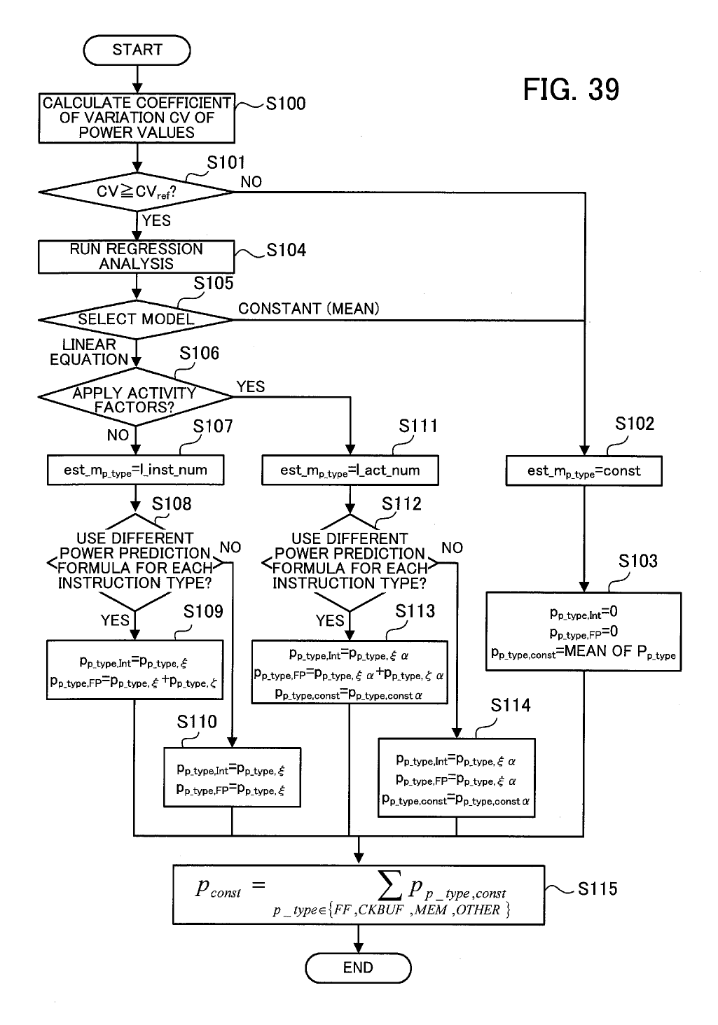

FIG. 39 is a flowchart illustrating an exemplified flow of the power library creation processing. Note that the sequence of individual processing steps is just an example, and the order of the processing steps may be changed accordingly. The processor 21 performs the following steps S100 to S114 for each classification p_type (for example, the flip-flop group, the clock line-associated cell group, the memory group, and the others group).

Steps S100, S101, S102, and S103 are almost the same as steps S80 to S83, respectively, of the power library creation processing of FIG. 28 above, and the power prediction formula for the classification p_type is modeled by the constant (the mean of the power values pₚ_{_{—}}_{type}). Note however that because the power library creation processing of the fifth embodiment does not use the model control variable est_iₚ_{_{—}}_{type}, no setting for the model control variable est_iₚ_{_{—}}_{type} is made in step S103. In addition, because the exemplified power library creation method of FIG. 39 does not use the coefficient pₚ_{_{—}}_{type, all}, both pₚ_{_{—}}_{type, Int} and pₚ_{_{—}}_{type, FP} are set to 0 in step S103.

On the other hand, when determining that CV≧CV_{ref} in step S101, the processor 21 runs regression analysis (step S104). In step S104, the regression analysis is run on the following two equations, using ξ=MIPSᵢₙₜ+MIPS_{FP}, ζ=MIPS_{FP}, ξ_{α}=αₚ_{_{—}}_{type ξ}, and ζ_{α}=αₚ_{_{—}}_{type}.

pₚ_{_{—}}_{type,ξ}ξ+pₚ_{_{—}}_{type,ζ}ζ+pₚ_{_{—}}_{type,const}=Pₚ_{_{—}}_{type} (18)

pₚ_{_{—}}_{type,ξα}ξ_{α}+pₚ_{_{—}}_{type,ζα}ζ_{α}+pₚ_{_{—}}_{type,const α}=Pₚ_{_{—}}_{type} (19)

The coefficients pₚ_{_{—}}_{type, ξ} and pₚ_{_{—}}_{type, ζ}, the constant pₚ_{_{—}}_{type, const}, and the coefficient of determination R² are obtained from the regression analysis on equation (18), and the coefficients pₚ_{_{—}}_{type, ξα} and pₚ_{_{—}}_{type, ζα}, the constant pₚ_{_{—}}_{type, constα}, and the coefficient of determination R_{α}² are obtained from the regression analysis on equation (19).

Subsequently, the processor 21 selects a model (step S105). In step S105, the processor 21 determines whether to model the power prediction formula by the constant (the mean) or a linear equation. For example, if the coefficient of determination R² or R_{α}² is 0.5 or more, the processor 21 considers that the power consumption has a strong correlation with the MIPS ratings, and determines to model the power prediction formula by a linear equation. If the coefficient of determination R² or R_{α}² is less than 0.5, the processor 21 considers that the power consumption has a poor correlation with the MIPS ratings, and determines to model the power prediction formula by the constant.

Instead of the coefficient of determination, the significance probability (p-value) of a test of the partial regression coefficient (t-test) may be used, for example. In this case, if p-value is less than or equal to a predetermined threshold (for example, 0.05), the processor 21 determines to model the power prediction formula by a linear equation, and if p-value exceeds the threshold, the processor 21 determines to model the power prediction formula by the constant.

When, in step S105, determining to model the power prediction formula by the constant (the mean), the processor 21 proceeds to step S102 described above. On the other hand, having determined to model the power prediction formula by a linear equation, the processor 21 determines whether to apply activity factors to the power prediction formula (step S106).

In step S106, based on, for example, R²≧R_{α}² or not, the processor 21 determines whether to apply activity factors to the power prediction formula. If R²≧R_{α}², the processor 21 considers that the correlation between the power consumption and the MIPS ratings with the activity factors applied is the same as or poorer than that without the activity factors, and therefore determines not to apply the activity factors to the power prediction formula. If R²<R_{α}², the processor 21 determines that the correlation between the power consumption and the MIPS ratings with the activity factors applied is stronger than that without the activity factors, and therefore determines to apply the activity factors to the power prediction formula.

In addition, instead of the coefficients of determination, for example, the significance probabilities (p-values) of tests of the partial regression coefficients (t-tests) on equations (18) and (19) may be used. If the p-value of the test of the partial regression coefficient (t-test) on equation (18) is less than or equal to the p-value of the test of the partial regression coefficient (t-test) on equation (19), the processor 21 determines not to apply the activity factors. In a case other than that, the activity factors may be applied.

When having determined not to apply the activity factors to the power prediction formula, the processor 21 proceeds to steps S107, S108, S109, and S110. Steps S107 to S110 are almost the same as steps S86 to S89, respectively, of FIG. 28. Note however that because the power library creation processing of the fifth embodiment does not use the model control variable est_iₚ_{_{—}}_{type}, no setting for the model control variable est_iₚ_{_{—}}_{type} is made in steps S109 and S110. In addition, because the exemplified power library creation method of FIG. 39 does not use the coefficient pₚ_{_{—}}_{type, all}, both pₚ_{_{—}}_{type, Int} and pₚ_{_{—}}_{type, FP} are set to pₚ_{_{—}}_{type, ξ} in step S110.

When having determined to apply the activity factors to the power prediction formula, the processor 21 proceeds to steps S111, S112, S113, and S114. In step S111, the processor 21 sets the model control variable est_mₚ_{_{—}}_{type} as est_mₚ_{_{—}}_{type}=l_act_num. In step S112, the processor 21 determines whether to use a different power prediction formula for each instruction type. Specifically, in step S112, the processor 21 runs a test of the partial regression coefficient, and determines to use a different power prediction formula for each instruction type when the test result indicates that the difference in power values between the instructions types is not able to be explained by sampling error alone (significant for ζ_{α}). On the other hand, the processor 21 determines not to use different power prediction formula according to the instruction types when the test result indicates that the difference in the power values is able to be explained by sampling error (insignificant for ζ_{α}).

When having determined to use a different power prediction formula for each instruction type, the processor 21 sets, in step S113, the coefficients pₚ_{_{—}}_{type, Int} and pₚ_{_{—}}_{type, FP} and the constant pₚ_{_{—}}_{type, const} as follows: pₚ_{_{—}}_{type, Int}=pₚ_{_{—}}_{type, ξα}; pₚ_{_{—}}_{type, FP}=pₚ_{_{—}}_{type, ξα}+pₚ_{_{—}}_{type, ζα}; and pₚ_{_{—}}_{type, const}=pₚ_{_{—}}_{type, constα}.

When having determined not to use different power prediction formulae according to the instruction types, the processor 21 sets, in step S114, the coefficients pₚ_{_{—}}_{type, Int} and pₚ_{_{—}}_{type, FP} and the constant pₚ_{_{—}}_{type, const} as follows: pₚ_{_{—}}_{type, Int}=pₚ_{_{—}}_{type, ξα}; pₚ_{_{—}}_{type, FP}=pₚ_{_{—}}_{type, ξα}; and pₚ_{_{—}}_{type, const}=pₚ_{_{—}}_{type, constα}.

Note that, in steps S110 and S114, instead of the coefficients pₚ_{_{—}}_{type, ξ} and pₚ_{_{—}}_{type, ξα}, a coefficient of a power prediction formula using only ξ as the parameter may be used. The power prediction formula using only ξ as the parameter is expressed as pₚ_{_{—}}_{type, all}ξ+pₚ_{_{—}}_{type, const}=Pₚ_{_{—}}_{type} or pₚ_{_{—}}_{type, allξα}+pₚ_{_{—}}_{type, constα}=Pₚ_{_{—}}_{type}, and the coefficient is pₚ_{_{—}}_{type, all}.

After the above-described processing is carried out for each classification p_type, the constant p_{const} is calculated based on equation (7) above (step S115). The model control variable est_mₚ_{_{—}}_{type}, the coefficient pₚ_{_{—}}_{type, i}_{_{—}}_{type}, and the constant p_{const} calculated in the above-described manner are then stored, for example, in the HDD 23 as a power library.

(Power Estimation Processing)

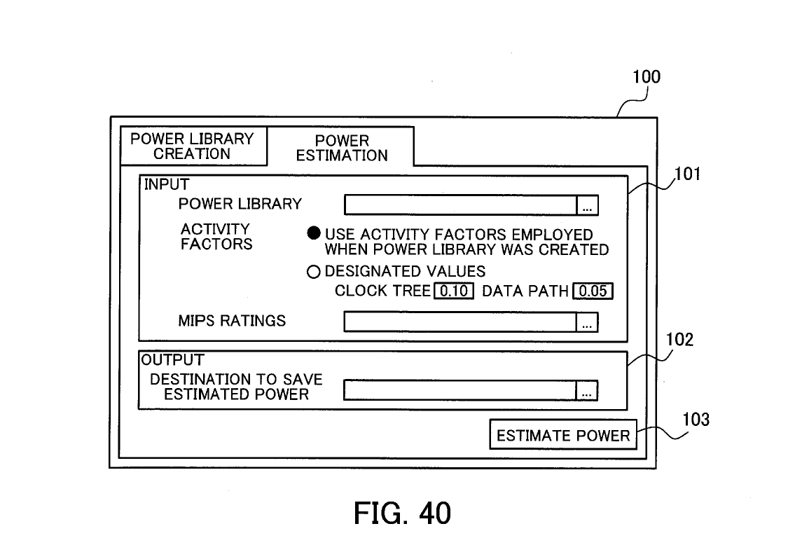

Next described is an example of power estimation processing of the power estimation method according to the fifth embodiment. FIG. 40 illustrates an example of a start screen of the power estimation processing. On a screen 100, the user designates files, including a power library and MIPS ratings, in an input file designation section 101. Further, as for activity factors to be used as a parameter, the input file designation section 101 allows the user to select either using activity factors employed when the power library was created or inputting designated values. When desiring to input designated values as the activity factors to be used, the user is allowed to input a clock tree activity factor and a data path activity factor in the input file designation section 101.

Note that the MIPS ratings and activity factors may be the same as or different from ones input when the power library was created. The MIPS ratings are acquired, for example, from simulations using an ISS, ESL simulations, or performance analysis information provided by processors. The activity factors are also acquired from the performance analysis information, for example. Alternatively, the user (designer) may input designated activity factors, as illustrated in FIG. 40, or activity factor default values calculated from the activity factors employed to create the power library may be used instead.

The user also designates the destination of estimated power to be calculated in an estimated power saving destination designation section 102. When a button 103 is pressed by the user operating the mouse 25b or the like, power estimation processing described below is carried out. In the power estimation processing, the processor 21 calculates estimated power Pest(MIPS_{Int}, MIPS_{FP}, α_{CK}, α_{DP}) based on equation (17), with reference to the input MIPS ratings (MIPS_{Int}, MIPS_{FP}), power library, and activity factors.

Note that, in equation (17), the function ν(est_mₚ_{_{—}}_{type}, p_type, i_type) is MIPSᵢ_{_{—}}_{type}αₚ_{_{—}}_{type} when the model control variable est_m is l_act_num, as described above. In addition, the function ν(est_mₚ_{_{—}}_{type}, p_type, i_type) is est_m=MIPSᵢ_{_{—}}_{type} when the model control variable est_m is other than l_act_num. A table for determining a value of the function ν(est_m_{ptype}, p_type, i_type) may be created as a power library so that the processor 21 is able to use, in the power estimation processing, a value in the table according to the model control variable est_m. This facilitates the power estimation processing.

In addition, by expressing the ν(est_mₚ_{_{—}}_{type}, p_type, i_type) using the following function ρ(est_m, p_type), the size of the table is made small. The function ρ(est_m, p_type) is the data path activity factor α_{DP} when the model control variable est_m is l_act_num and the classification p_type is the others group (“OTHER”). On the other hand, the function ρ(est_m, p_type) is the clock tree activity factor α_{cK} when the model control variable est_m is l_act_num and the classification p_type is the flip-flop, clock buffer, or memory group. In addition, the function ρ(est_m, p_type) is 1 when the condition is other than the above.

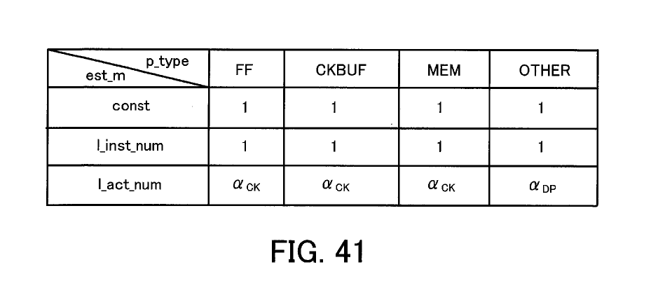

The function ρ(est_m, p_type) is represented, for example, by the following table. FIG. 41 illustrates an example of a table for the function ρ(est_m, p_type). The function ρ(est_m, p_type) takes the clock tree activity factor α_{cK} when the model control variable est_m is l_act_num and the classification p_type is the flip-flop, clock buffer, or memory group, and takes the data path activity factor α_{DP} when the model control variable est_m is l_act_num and the classification p_type is the others group. When the model control variable est_m is const or l_inst_num, the function ρ(est_m, p_type) takes 1 regardless of the classification p_type.

Using the function ρ(est_m, p_type), the function ν(est_mₚ_{_{—}}_{type}, p_type, i_type) is expressed as follows: ν(est_mₚ_{_{—}}_{type}, p_type, i_type)=MIPSᵢ_{_{—}}_{type}ρ(est_m, p_type). Then, in the power estimation processing, the processor 21 acquires a value of the function ρ(est_m, p_type) according to the model control variable est_m and the classification p_type by referring to the table of FIG. 41 stored, for example, in the HDD 23. Then, the processor calculates the function ν(est_mₚ_{_{—}}_{type}, p_type, i_type) based on the acquired value of the function ρ(est_m, p_type) and MIPSᵢ_{_{—}}_{type}, and applies the calculated function ν(est_mₚ_{_{—}}_{type}, p_type, i_type) to the power model of equation (17) to thereby calculate estimated power.

The power estimation method of the fifth embodiment described above achieves the same effect as that of the fourth embodiment, and further enables more highly accurate estimation of power consumption by taking account of the activity factors of the individual power consuming factor groups. In addition, when more highly accurate calculation of power consumption is achieved without taking account of the activity factors (i.e., when the MIPS ratings multiplied by the activity factors have a poor correlation with the power consumption), the power model is created with no consideration for the activity factors. As a result, a simple power model is created, and thus the calculated amount of power estimation is reduced.

### (f) Sixth Embodiment

Next described is a power estimation method according to a sixth embodiment. As for a power estimating apparatus, the power estimating apparatus 20 of FIG. 2 is applicable. The above-described power estimation methods of the fourth and fifth embodiments assume that it is possible to measure MIPS ratings separately for integer-type and floating-point-type instructions. According to the power estimation method of the sixth embodiment below, measurable MIPS ratings are totals of MIPS ratings of the individual instruction types.

According to the power estimation method of the sixth embodiment, information on a predominant instruction type in a program run on each sample (a semiconductor integrated circuit including a processor, such as a CPU and a DSP) is provided, for example, by the user so that the processor 21 is able to determine instruction types. For example, the provided information indicates whether integer-type instructions or floating-point-type instructions are predominantly included in the program.

Power prediction formulae created in the power estimation method of the sixth embodiment are almost the same as, for example, equation (8) in the case of leaving the activity factors out of consideration and equation (17) in the case of taking into account the activity factors. Note however that, because MIPS ratings are not acquired for each instruction type i_type, the Σ term no longer includes the instruction type i_type as its variable, and thus an instruction-type specific power prediction formula is created for each instruction type i_type.

In the sixth embodiment also, the processor 21 acquires input data including MIPS ratings and power values, and calculates the above-described model control variable est_m, coefficient pₚ_{_{—}}_{type, i}_{_{—}}_{type}, and constant p_{const, i}_{_{—}}_{type} by regression analysis and tests based on the input data.

The flow of the power estimation method according to the sixth embodiment is the same as that of FIG. 3. Note however that the power estimation method of the sixth embodiment uses the following information as the input data in addition to MIPS ratings and power values: information on a predominant instruction type i_type of each sample; and information on activity factors in the case of taking account of the activity factors. Next described is an example of a method of acquiring the input data.

(Input Data Acquisition Method)

Power values, a MIPS value, and activity factors for each sample are acquired by the processing illustrated in FIG. 36 above. Note however that each MIPS value acquired in the power estimation method of the sixth embodiment is not a MIPS value specific to each instruction type i_type, but a total of MIPS ratings of the individual instruction types i_type. In addition to the input data, the processor 21 also acquires information on a predominant instruction type i_type of each sample, for example, from the user. Note that, at this time, the processor 21 may acquire a different parameter of Samples 1 to n, in addition to the MIPS ratings.

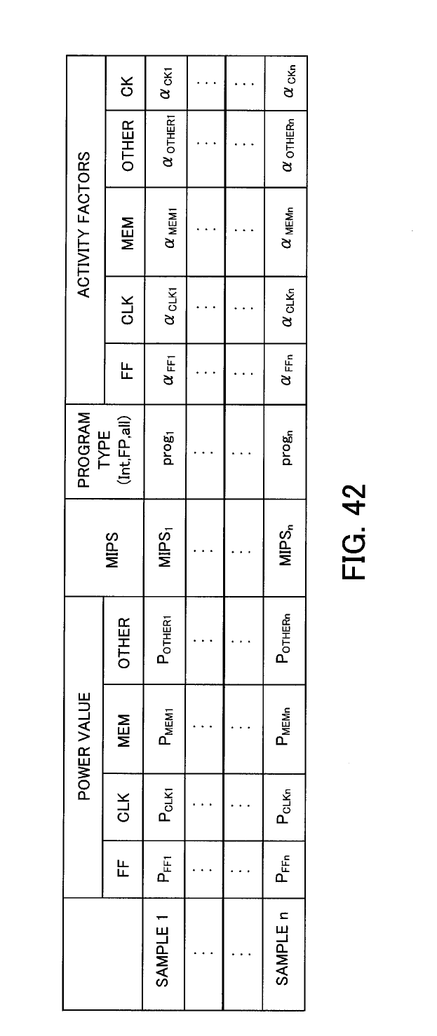

FIG. 42 illustrates an example of the acquired input data. In FIG. 42, program types prog₁ to progₙ of the samples are listed, in addition to power values, a MIPS rating, and activity factors of each sample. Each of the program types prog₁ to progₙ indicates a predominant instruction type i_type, and is denoted by “Int” when integer-type instructions are predominant, “FP” when floating-point-type instructions are predominant, and “all” when neither type is predominant. Note that activity factors may not be acquired in the case where no consideration is given for the activity factors.

The input data is stored in a memory unit such as the HDD 23. Subsequently, the processor 21 acquires (reads) the input data, for example, from the HDD 23 to create a power library.

(Power Library Creation Processing)

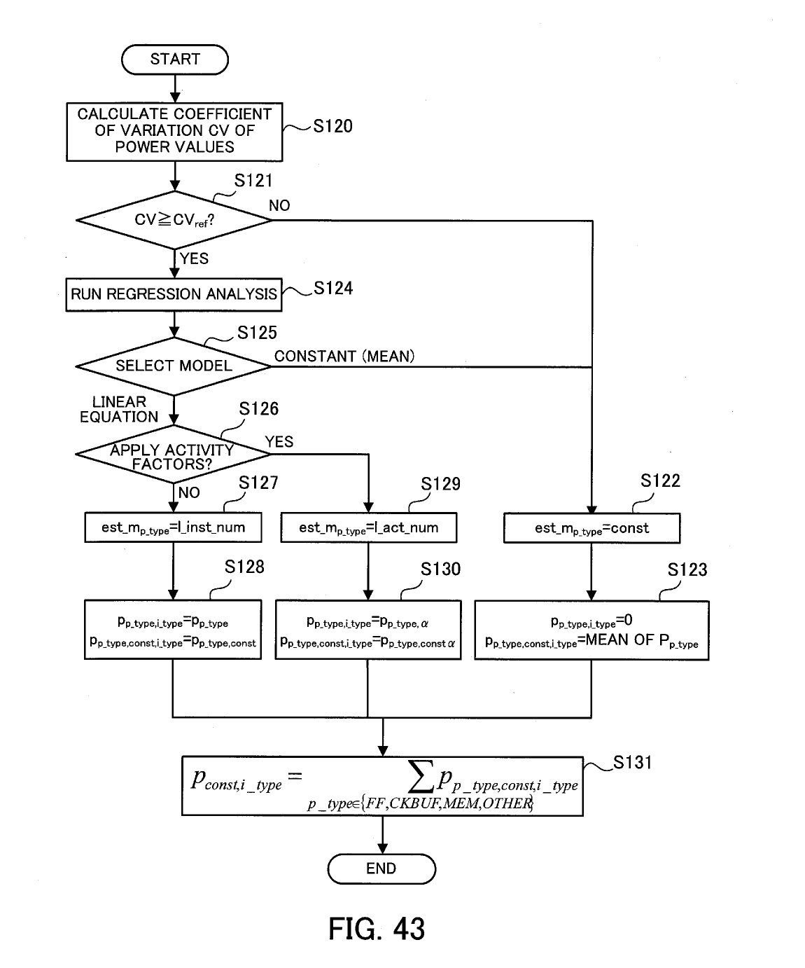

Next described is an example of power library creation processing of the power estimation method according to the sixth embodiment. FIG. 43 is a flowchart illustrating an exemplified flow of the power library creation processing. Note that the example of FIG. 43 is the power library creation processing taking account of activity factors, however, steps S126, S129, and S130 are not carried out when no consideration is given for the activity factors. The sequence of individual processing steps is just an example, and the order of the processing steps may be changed accordingly.

The processor 21 performs the following steps S120 to S130 for each of the classifications p_type (for example, each of the flip-flop group, the clock line-associated cell group, the memory group, and the others group) and the instruction types i_type (Int, FP, and all described above). As a result, the coefficient pₚ_{_{—}}_{type, i}_{_{—}}_{type} and the constant pₚ_{_{—}}_{type, const, i}_{_{—}}_{type} are calculated for each instruction type i_type.

Steps S120, S121, S122, and S123 are almost the same as steps S100 to S103, respectively, of FIG. 39 above, and the power prediction formula for the classification p_type and the instruction type i_type is modeled by the constant (the mean of the power values Pₚ_{_{—}}_{type}). Note however that because the power library creation processing of the sixth embodiment does not use the instruction type-specific coefficients pₚ_{_{—}}_{type, Int} and pₚ_{_{—}}_{type, FP} according to the instruction type i_type, the coefficient pₚ_{_{—}}_{type, i}_{_{—}}_{type} is used and set as pₚ_{_{—}}_{type, i}_{_{—}}_{type}=0 in step S123.

On the other hand, when determining that CV≧CV_{ref} in step S121, the processor 21 runs regression analysis (step S124). Samples targeted in step S124 are, amongst Samples 1 to n of FIG. 42, those whose program types prog₁ to progₙ becomes Int or FP when the instruction type i_type is Int or FP. When the instruction type i_type is “all”, all of the Samples 1 to n of FIG. 42 are targeted.

In step S124, the regression analysis is run on the following two equations, using ξ_{α}=αₚ_{_{—}}_{type}MIPS.

pₚ_{_{—}}_{type}MIPS+pₚ_{_{—}}_{type,const}=Pₚ_{_{—}}_{type} (20)

pₚ_{_{—}}_{type,α}ξ_{α}+pₚ_{_{—}}_{type,const α}=Pₚ_{_{—}}_{type} (21)

The coefficient pₚ_{_{—}}_{type}, the constant pₚ_{_{—}}_{type, coast}, and the coefficient of determination R² are obtained from the regression analysis on equation (20), and the coefficients pₚ_{_{—}}_{type, α}, the constant pₚ_{_{—}}_{type, constα}, and the coefficient of determination R_{α}² are obtained from the regression analysis on equation (21).

The subsequent steps S125, S126, S127, and S129 are the same as steps S105 to S107 and S111, respectively, of FIG. 39. Note however that, after step 127 and S129, the processor 21 proceeds to step S128 and S130, respectively, without determining whether to use a different power prediction formula for each instruction type. In step S128, the processor 21 sets the coefficient pₚ_{_{—}}_{type, i}_{_{—}}_{type} and the constant pₚ_{_{—}}_{type, const, i}_{_{—}}_{type} as pₚ_{_{—}}_{type, i}_{_{—}}_{type}=pₚ_{_{—}}_{type}, and pₚ_{_{—}}_{type, const, i}_{_{—}}_{type}=pₚ_{_{—}}_{type, const}. In step S130, the processor 21 sets the coefficient pₚ_{_{—}}_{type, i}_{_{—}}_{type} and the constant pₚ_{_{—}}_{type, const, i}_{_{—}}_{type} as pₚ_{_{—}}_{type, i}_{_{—}}_{type}=pₚ_{_{—}}_{type, α}, and pₚ_{_{—}}_{type, const, i}_{_{—}}_{type}=pₚ_{_{—}}_{type, constα}.

After the above-described processing is carried out for each classification p_type and each instruction type i_type, the constant p_{const} is calculated based on equation (7) above (step S131). Note however that because power prediction formulae for the individual instruction types i_type are calculated, constants p_{const, i}_{_{—}}_{type} and pₚ_{_{—}}_{type, const, i}_{_{—}}_{type} are used instead of the constants p_{const} and pₚ_{_{—}}_{type, const}. The model control variable est_mₚ_{_{—}}_{type}, coefficient pₚ_{_{—}}_{type, i}_{_{—}}_{type}, and constant p_{const, i}_{_{—}}_{type} calculated in the above-described manner are then stored, for example, in the HDD 23 as a power library.

Further, the above-described power library creation processing may be combined with the processing described in FIGS. 4 to 6. Herewith, even when different parameters in addition to the MIPS ratings are used, a simple power model with a reduced number of parameters, or using the mean power, is created in consideration of the power consumption of the processor of the power estimation target apparatus.

(Power Estimation Processing)

Although the power estimation processing of the sixth embodiment is almost the same as that of the fourth or fifth embodiment, the power estimation processing of the sixth embodiment designates a predominant instruction type as input data in addition to a predicted MIPS rating and predicted activity factors (in the case of taking account of the activity factors) of a power estimation target. For example, in the case where integer-type instructions are predominant, consumption power of the power estimation target is estimated using the coefficient pₚ_{_{—}}_{type, i}_{_{—}}_{type} and the constant p_{const, i}_{_{—}}_{type} defined when the instruction type i_type is Int, selected from the power library. On the other hand, in the case where floating-point-type instructions are predominant, consumption power of the power estimation target is estimated using the coefficient pₚ_{_{—}}_{type, i}_{_{—}}_{type} and the constant p_{const, i}_{_{—}}_{type} defined when the instruction type i_type is FP, selected from the power library. Further, in the case where neither integer-type instructions nor floating-point-type instructions are predominant, consumption power of the power estimation target is estimated using the coefficient pₚ_{_{—}}_{type, i}_{_{—}}_{type} and the constant p_{const, i}_{_{—}}_{type} defined when the instruction type i_type is “all”, selected from the power library.

According to the power estimation method of the sixth embodiment described above, the same effect as in the power estimation method of the fourth or fifth embodiment is achieved even when instruction type-specific MIPS ratings are not available.

Note that, in the power estimation methods of the fourth to sixth embodiments described above, MIPS ratings and activity factors are used as parameters, however, other parameters may be added. For example, when RAM access occurs due to cache access in a processor having cache memory, power consumption due to the RAM access takes place in addition to power consumption caused by instruction execution. Therefore, estimating power consumption without distinguishing instruction executions involving and not involving cache access leads to an error in the estimation.

In addition, due to a cache miss, for example, a data hazard (mainly when a read miss occurs) or a buffer full (mainly at the time of a write operation in write-through mode) occurs, and these phenomena are observed as a decrease in the MIPS rating of the CPU. Therefore, no consideration for cache misses is a source of error.

Therefore, it is desirable to add cache access information or cache miss information as a parameter. The cache access information is, for example, the number of instruction cache accesses and the number of data cache accesses, per unit time. The cache miss information is, for example, the number of instruction cache misses and the number of data cache misses, per unit time. The power estimation with the cache access information or the cache miss information added as a parameter may be carried out in the same manner as the processing flow of FIG. 3. The cache access information or the cache miss information is acquired by measuring samples, for example, by using a hardware performance counter or the like. Power values may be measured at the same time as the measurement by the performance counter, however, if it is not desired to include the power consumed by the performance counter, the power values are measured separately.

In addition, the number of system calls per unit time may be added as a parameter. A system call which is an application running on the operating system is also observed as a decrease in the MIPS rating of the CPU. In addition, because operations differ according to the types of system calls, no consideration for the types of system calls is a source of error.

Therefore, it is desirable to add system call information as a parameter. The system call information is, for example, the number of read system calls, the number of write system calls, or the number of other system calls, per unit time. The power estimation with the system call information added as a parameter may also be carried out in the same manner as the processing flow of FIG. 3. The system call information is acquired by obtaining the history of system calls of a program, for example, using the Linux (registered trademark) strace command and then measuring the number of system calls per unit time according to each type of system calls based on the run time of the program. Because the overhead is significant, it is desirable to perform the process of acquiring the history of system calls of the program separately from the process of measuring the run time of the program and measure power values during the process of measuring the run time of the program.

Note that an application programming interface (API, a system call or a library call) of an instruction-trace based power prediction may be handled in a like manner.

According to the power estimation method, the power estimating apparatus, and the program of one aspect, an increase in the calculated amount of power estimation calculation is reduced.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A power estimation method comprising:
acquiring, by a first processor, a plurality of power values consumed by a power estimation target apparatus, each of the power values corresponding to a plurality of parameters;
calculating, by the first processor, magnitude of variation in the acquired power values in relation to a mean of the power values;
creating, by the first processor, a first power prediction formula when the magnitude of variation is less than a first value, the first power prediction formula approximating power consumption of the power estimation target apparatus by a constant which is the mean;
calculating, by the first processor, a degree of influence of each of the parameters on the power consumption when the magnitude of variation is more than or equal to the first value;
creating, by the first processor, a second power prediction formula by reducing number of the parameters based on the degree of influence, the second power prediction formula approximating the power consumption by a linear equation; and
estimating, by the first processor, the power consumption using one of the first power prediction formula and the second power prediction formula.

2. The power estimation method according to claim 1, wherein:
the first processor calculates the degree of influence by running regression analysis and a test based on the parameters and the power values, and creates the second power prediction formula by removing at least one of the parameters, having least influence on the power consumption.

3. The power estimation method according to claim 2, wherein:
the first processor
calculates, from the regression analysis, coefficients corresponding one-to-one with the parameters of the second power prediction formula,
calculates, by the test, significance probability of each of the coefficients and
determines that, amongst parameters corresponding to coefficients each of whose significance probabilities is more than a second value, at least a parameter corresponding to a coefficient with a largest significance probability has the least influence on the power consumption, and removes the determined parameter.

4. The power estimation method according to claim 2, wherein:
the first processor
calculates a coefficient of determination representing accuracy of a regression equation obtained from the regression analysis or a significance probability in a test of the coefficient of determination, and
estimates the power consumption using the first power prediction formula when the coefficient of determination is less than a third value or when the significance probability is more than a fourth value.

5. The power estimation method according to claim 1, wherein:
the first processor asks a user for approval or prompts the user to check the parameters or the power values prior to creating the first power prediction formula or reducing the number of the parameters.

6. The power estimation method according to claim 1, wherein:
the first processor presents a user with changes in evaluation results of the power consumption estimated when a change has been made to the parameters used to create the second power prediction formula.

7. The power estimation method according to claim 1, wherein:
the power estimation target apparatus includes a second processor, and the first processor acquires a value of a first parameter and a value of a second parameter together with the power values corresponding one-to-one with classifications of power consuming factors, the value of the first parameter being obtained when a first type instruction is executed by the second processor, and the value of the second parameter being obtained when a second type instruction is executed by the second processor,
the first processor calculates a degree of influence of the first parameter and the second parameter on the power consumption by running regression analysis and a test based on the first parameter, the second parameter, and the power values, and
the first processor creates the second power prediction formula using a third parameter obtained by adding the first parameter and the second parameter when determining that a change in the power consumption caused by using the first parameter and the second parameter separately falls within a range of error.

8. The power estimation method according to claim 7, wherein:
when determining that the change in the power consumption falls outside the range of error, the first processor creates a third power prediction formula using the first parameter and the second parameter, and estimates the power consumption using the third power prediction formula.

9. The power estimation method according to claim 7, wherein:
the first type instruction predominantly involves integer arithmetic, and the second type instruction predominantly involves floating-point arithmetic, and
the first parameter is a million instructions per second (MIPS) rating obtained when the first type instruction is executed, and the second parameter is a MIPS rating obtained when the second type instruction is executed.

10. The power estimation method according to claim 7, wherein:
the first processor creates the second power prediction formula based on the first parameter and the second parameter, individually multiplied by an activity factor of each of the classifications of power consuming factors, and the third parameter.

11. The power estimation method according to claim 10, wherein:
the activity factor of each of the classifications of power consuming factors is approximated by one of an activity factor of a clock tree and an activity factor of a data path.

12. The power estimation method according to claim 7, wherein:
the first processor acquires a sum of the value of the first parameter and the value of the second parameter and program type information indicating a predominant type of instruction in a program run on the second processor, and
the first processor creates the first power prediction formula or the second power prediction formula according to the predominant type of instruction indicated by the program type information.

13. A power estimating apparatus comprising:
a memory configured to store a plurality of power values consumed by a power estimation target apparatus, each of the power values corresponding to a plurality of parameters; and
a processor configured to perform a procedure including:
acquiring the power values,
calculating magnitude of variation in the acquired power values in relation to a mean of the power values,
creating a first power prediction formula when the magnitude of variation is less than a first value, the first power prediction formula approximating power consumption of the power estimation target apparatus by a constant which is the mean,
calculating a degree of influence of each of the parameters on the power consumption when the magnitude of variation is more than or equal to the first value,
creating a second power prediction formula by reducing number of the parameters based on the degree of influence, the second power prediction formula approximating the power consumption by a linear equation, and
estimating the power consumption using one of the first power prediction formula and the second power prediction formula.

14. A computer-readable storage medium storing a computer program, the computer program causing a computer to perform a procedure comprising:
acquiring a plurality of power values consumed by a power estimation target apparatus, each of the power values corresponding to a plurality of parameters;
calculating magnitude of variation in the acquired power values in relation to a mean of the power values;
creating a first power prediction formula when the magnitude of variation is less than a first value, the first power prediction formula approximating power consumption of the power estimation target apparatus by a constant which is the mean;
calculating a degree of influence of each of the parameters on the power consumption when the magnitude of variation is more than or equal to the first value;
creating a second power prediction formula by reducing number of the parameters based on the degree of influence, the second power prediction formula approximating the power consumption by a linear equation; and
estimating the power consumption using one of the first power prediction formula and the second power prediction formula.
